(19) United States
(12) Patent Application Publication
(10) Pub. No.: US 2025/0068065 A1
(43) Pub. Date: Feb. 27, 2025

(54) ENHANCED EUV UNDERLAYER EFFECT WITH DIFFUSION BARRIER LAYER

(71) Applicant: Lam Research Corporation, Fremont, CA (US)

(72) Inventors: Sivananda Krishnan Kanakasabapathy, Pleasanton, CA (US); Kevin M. McLaughlin, Sherwood, OR (US); Jialing Yang, Sherwood, OR (US); Arpan Pravin Mahorowala, West Linn, OR (US); Durgalakshmi Singhal, Beaverton, OR (US)

(21) Appl. No.: 18/727,056

(22) PCT Filed: Jan. 9, 2023
(86) PCT No.: PCT/US2023/060306

§ 371 Date: Jul. 5, 2024

Related U.S. Application Data
(60) Provisional application No. 63/267,246, filed on Jan. 28, 2022.

(51) Int. Cl. G03F 7/004; G03F 7/09

(52) U.S. Cl. CPC G03F 7/0042; G03F 7/091; G03F 7/094

(57) ABSTRACT

This disclosure relates generally to a patterning structure (and methods and apparatus for forming such structures) including substrate having a partially fabricated semiconductor device film stack, a radiation-sensitive imaging layer over the substrate, an underlayer below the radiation-sensitive imaging layer, the underlayer including a labile species, a hardmask positioned below the underlayer, and a diffusion barrier layer positioned between the underlayer and the hardmask layer, the diffusion barrier layer including a diffusion barrier material that reduces diffusion of the labile species from the underlayer into the hardmask layer. In various embodiments, the reduction of diffusion of the labile species downwards from the underlayer into the hardmask results in relatively greater diffusion of the labile species upwards from the underlayer into the radiation-sensitive imaging layer. This increased diffusion into the radiation-sensitive imaging layer may advantageously increase radiation absorptivity and/or patterning performance of the radiation-sensitive imaging layer.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### FIELD

This disclosure relates generally to the field of semiconductor processing, and in particular to extreme ultraviolet (EUV) photoresist (PR) lithography techniques and materials.

### BACKGROUND

As semiconductor fabrication continues to advance, feature sizes continue to shrink, and new processing methods are needed. One area where advances are being made is in the context of patterning, for example using photoresist materials that are sensitive to lithographic radiation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, materials, apparatus, and systems for depositing a diffusion barrier layer, or a stack including a diffusion barrier layer, on a substrate. The diffusion barrier layer may be provided to reduce or avoid diffusion in one direction, thereby promoting diffusion in another direction. This control of diffusion encourages the migration of labile species as desired within a stack of materials. Such migration can be utilized to enhance desired properties of relevant materials.

In one aspect of the disclosed embodiments, a patterning structure is provided, the patterning structure including: a substrate including a partially fabricated semiconductor device film stack; a radiation-sensitive imaging layer disposed over the substrate; an underlayer positioned below the radiation-sensitive imaging layer, the underlayer including a labile species; a hardmask layer positioned below the underlayer; and a diffusion barrier layer positioned between the underlayer and the hardmask layer, the diffusion barrier layer including a diffusion barrier material that reduces diffusion of the labile species from the underlayer into the hardmask layer.

In various implementations, the diffusion barrier material may include a material selected from the group consisting of an oxide material, a nitride material, a carbide material, silicon, a silicide material, a sulfide material, a metal-containing material, or a combination thereof. For instance, in some cases the diffusion barrier layer may include the oxide material. In some such cases, the oxide material may be a material selected from the group consisting of a metal oxide, a silicon oxide, a metal oxynitride, a silicon oxynitride, a metal oxycarbide, a silicon oxycarbide, or a combination thereof. In some such cases, the oxide may be a metal oxide. In these or other embodiments, the diffusion barrier material may include a metal selected from the group consisting of aluminum, titanium, molybdenum, tungsten, tin, or a combination thereof. In these or other embodiments, the diffusion barrier material may include the nitride material. In some such cases, the nitride material may be a material selected from the group consisting of a metal nitride, a silicon nitride, a metal oxynitride, a silicon oxynitride, or a combination thereof. In some such cases, the nitride may be a metal nitride. In some such cases, the diffusion barrier material may include a metal selected from the group consisting of aluminum, molybdenum, tungsten, tin, or a combination thereof. In some cases, the diffusion barrier material may include silicon nitride. In these or other embodiments, the diffusion barrier material may include the carbide material. In some such embodiments, the carbide material may be a material selected from the group consisting of a metal carbide, a silicon carbide, a metal oxycarbide, a silicon oxycarbide, or a combination thereof, and optionally where the diffusion barrier material includes a metal selected from the group consisting of aluminum, titanium, molybdenum, tungsten, tin, or a combination thereof. In some such cases, the diffusion barrier material includes the silicon carbide. In some such cases, the silicon carbide may be doped. For example, the silicon carbide may be doped with at least one of nitrogen and oxygen.

In various implementations, the labile species may be hydrogen. In these or other embodiments, the radiation-sensitive imaging layer may include a photoresist material. In some such cases, the photoresist material may be a metal-containing photoresist material. In some such cases, the photoresist material is a metal-organic-containing photoresist material.

The underlayer may have a variety of compositions. In various embodiments, the underlayer may include a hydrogen-containing carbon layer including at least one dopant, where the at least one dopant is a dopant selected from the group consisting of oxygen, silicon, nitrogen, tungsten, boron, iodine, chlorine, or a combination thereof. In these or other embodiments, the diffusion barrier layer may be deposited using a dry vapor-based deposition technique or using a wet liquid-based deposition technique. In various embodiments, the diffusion barrier layer may reduce diffusion of the labile species from the underlayer into the hardmask layer by at least about 60%. In some cases, the diffusion barrier layer may reduce diffusion of the labile species from the underlayer into the hardmask layer by at least about 90%.

In another aspect of the disclosed embodiments, a method of making a patterning structure is provided, the method including: providing a substrate having a hardmask layer thereon; depositing a diffusion barrier layer over the hardmask layer, the diffusion barrier layer including a diffusion barrier material; depositing an underlayer over the diffusion barrier layer, the underlayer including a labile species; and depositing a radiation-sensitive imaging layer over the underlayer, where the diffusion barrier layer reduces diffusion of the labile species from the underlayer into the hardmask layer.

In various implementations, the diffusion barrier material may include a material selected from the group consisting of an oxide material, a nitride material, a carbide material, silicon, a silicide material, a sulfide material, a metal-containing material, or a combination thereof. For instance, in some cases the diffusion barrier layer may include the oxide material. In some such cases, the oxide material may be a material selected from the group consisting of a metal oxide, a silicon oxide, a metal oxynitride, a silicon oxynitride, a metal oxycarbide, a silicon oxycarbide, or a combination thereof. In some such cases, the oxide may be a metal oxide. In these or other embodiments, the diffusion barrier material may include a metal selected from the group consisting of aluminum, titanium, molybdenum, tungsten, tin, or a combination thereof. In these or other embodiments, the diffusion barrier material may include the nitride material. In some such cases, the nitride material may be a material selected from the group consisting of a metal nitride, a silicon nitride, a metal oxynitride, a silicon oxynitride, or a combination thereof. In some such cases, the nitride may be a metal nitride. In some such cases, the diffusion barrier material may include a metal selected from the group consisting of aluminum, molybdenum, tungsten, tin, or a combination thereof. In some cases, the diffusion barrier material may include silicon nitride. In these or other embodiments, the diffusion barrier material may include the carbide material. In some such embodiments, the carbide material may be a material selected from the group consisting of a metal carbide, a silicon carbide, a metal oxycarbide, a silicon oxycarbide, or a combination thereof, and optionally where the diffusion barrier material includes a metal selected from the group consisting of aluminum, titanium, molybdenum, tungsten, tin, or a combination thereof. In some such cases, the diffusion barrier material includes the silicon carbide. In some such cases, the silicon carbide may be doped. For example, the silicon carbide may be doped with at least one of nitrogen and oxygen.

In various implementations, the labile species may be hydrogen. In these or other embodiments, the radiation-sensitive imaging layer may include a photoresist material. In some such cases, the photoresist material may be a metal-containing photoresist material. In some such cases, the photoresist material is a metal-organic-containing photoresist material.

The underlayer may have a variety of compositions. In various embodiments, the underlayer may include a hydrogen-containing carbon layer including at least one dopant, where the at least one dopant is a dopant selected from the group consisting of oxygen, silicon, nitrogen, tungsten, boron, iodine, chlorine, or a combination thereof. In these or other embodiments, the diffusion barrier layer may be deposited using a dry vapor-based deposition technique or using a wet liquid-based deposition technique. In various embodiments, the diffusion barrier layer may reduce diffusion of the labile species from the underlayer into the hardmask layer by at least about 60%. In some cases, the diffusion barrier layer may reduce diffusion of the labile species from the underlayer into the hardmask layer by at least about 90%.

In another aspect of the disclosed embodiments, an apparatus for making a patterning structure on a substrate is provided, the apparatus including: a process chamber including a substrate support; a process gas source connected with the process chamber and associated flow-control hardware; and a controller having a processor and a memory, wherein the processor and the memory are communicatively connected with one another, the processor is at least operatively connected with the flow-control hardware, and the memory stores computer-executable instructions for causing any of the methods claimed or otherwise described herein.

For example, in one embodiment, the memory may store computer-executable instructions for causing: providing a substrate having a hardmask layer thereon to the process chamber; depositing a diffusion barrier layer over the hardmask layer, the diffusion barrier layer including a diffusion barrier material; depositing an underlayer over the diffusion barrier layer, the underlayer including a labile species; and depositing a radiation-sensitive imaging layer over the underlayer, where the diffusion barrier layer reduces diffusion of the labile species from the underlayer into the hardmask layer.

In related embodiments, the memory may store a subset of these instructions, for example to deposit the diffusion barrier layer, optionally in combination with any other instructions described herein.

In various implementations, the diffusion barrier material may include a material selected from the group consisting of an oxide material, a nitride material, a carbide material, silicon, a silicide material, a sulfide material, a metal-containing material, or a combination thereof. For instance, in some cases the diffusion barrier layer may include the oxide material. In some such cases, the oxide material may be a material selected from the group consisting of a metal oxide, a silicon oxide, a metal oxynitride, a silicon oxynitride, a metal oxycarbide, a silicon oxycarbide, or a combination thereof. In some such cases, the oxide may be a metal oxide. In these or other embodiments, the diffusion barrier material may include a metal selected from the group consisting of aluminum, titanium, molybdenum, tungsten, tin, or a combination thereof. In these or other embodiments, the diffusion barrier material may include the nitride material. In some such cases, the nitride material may be a material selected from the group consisting of a metal nitride, a silicon nitride, a metal oxynitride, a silicon oxynitride, or a combination thereof. In some such cases, the nitride may be a metal nitride. In some such cases, the diffusion barrier material may include a metal selected from the group consisting of aluminum, molybdenum, tungsten, tin, or a combination thereof. In some cases, the diffusion barrier material may include silicon nitride. In these or other embodiments, the diffusion barrier material may include the carbide material. In some such embodiments, the carbide material may be a material selected from the group consisting of a metal carbide, a silicon carbide, a metal oxycarbide, a silicon oxycarbide, or a combination thereof, and optionally where the diffusion barrier material includes a metal selected from the group consisting of aluminum, titanium, molybdenum, tungsten, tin, or a combination thereof. In some such cases, the diffusion barrier material includes the silicon carbide. In some such cases, the silicon carbide may be doped. For example, the silicon carbide may be doped with at least one of nitrogen and oxygen.

In various implementations, the labile species may be hydrogen. In these or other embodiments, the radiation-sensitive imaging layer may include a photoresist material. In some such cases, the photoresist material may be a metal-containing photoresist material. In some such cases, the photoresist material is a metal-organic-containing photoresist material.

The underlayer may have a variety of compositions. In various embodiments, the underlayer may include a hydrogen-containing carbon layer including at least one dopant, where the at least one dopant is a dopant selected from the group consisting of oxygen, silicon, nitrogen, tungsten, boron, iodine, chlorine, or a combination thereof. In these or other embodiments, the diffusion barrier layer may be deposited using a dry vapor-based deposition technique or using a wet liquid-based deposition technique. In various embodiments, the diffusion barrier layer may reduce diffusion of the labile species from the underlayer into the hardmask layer by at least about 60%. In some cases, the diffusion barrier layer may reduce diffusion of the labile species from the underlayer into the hardmask layer by at least about 90%.

These and other aspects are described further below with reference to the drawings.

### BRIEF DESCRIPTION OF THE DRAWINGS

FIG. 1A depicts a substrate having a stack of materials thereon, the stack of materials being suitable for use in connection with patterning operations.

FIGS. 1B and 1C show the concentration profile of a labile species within the stack of materials shown in FIG. 1A, with pre-diffusion concentration shown in FIG. 1B and post-diffusion concentration shown in FIG. 1C.

FIG. 2A depicts a substrate having a stack of materials thereon, the stack of materials including a diffusion barrier layer and being suitable for use in connection with patterning operations.

FIGS. 2B and 2C show the concentration profile of a labile species within the stack of materials shown in FIG. 2A, with pre-diffusion concentration shown in FIG. 2B and post-diffusion concentration shown in FIG. 2C.

FIGS. 3A and 3B illustrate desirable reactions that can occur between an underlayer and a radiation-sensitive imaging layer.

FIG. 4 provides a flowchart for a method in accordance with various embodiments.

FIG. 5 presents a schematic illustration of an embodiment of a process station 500 according to various embodiments.

FIG. 6 presents a schematic illustration of an embodiment of a multi-station processing tool 600 according to various embodiments.

FIG. 7 presents a schematic illustration of an embodiment of an inductively coupled plasma apparatus 700 according to various embodiments.

FIG. 8 presents a schematic illustration of an embodiment of a semiconductor process cluster tool architecture 800 according to various embodiments.

FIG. 9 depicts a cross-sectional schematic view of an example of a dry deposition apparatus 900 according to various embodiments.

FIG. 10 depicts detail side section and plan views of a portion of a top plate, substrate, and edge ring shown in FIG. 9

FIG. 11 depicts experimental results that demonstrate the effectiveness of a diffusion barrier layer in reducing unwanted diffusion.

FIGS. 12A-12C show substrate structures that were evaluated in connection with FIG. 11.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Various embodiments herein relate to methods, apparatus, and structures for improving the efficiency at which a photoresist scanner induces chemical changes in a radiation-sensitive imaging layer. This increased efficiency is often referred to as a lower Dose-to-Size (DtS), and generally means that the chemical changes desired during photolithography (and related operations) can be achieved with a relatively lower dose of patterning radiation provided to the substrate. Such reductions in radiation dose are extremely valuable in the context of semiconductor patterning, especially when practicing extreme ultraviolet (EUV) photolithography, which is still relatively costly. In order to achieve this increased efficiency/lower DtS, a diffusion barrier layer is provided at an appropriate location within a film stack on a substrate (e.g., above a hardmask and below an underlayer). The diffusion barrier layer minimizes diffusion of a labile species in a particular direction (e.g., downward into the hardmask), and concurrently maximizes diffusion of the labile species in the opposite direction (e.g., upward into the underlayer). This preferential directional diffusion causes desirable chemical changes within the radiation-sensitive imaging layer, which result in a lower DtS.

It should be understood that while the present disclosure relates to lithographic patterning techniques and materials exemplified by extreme ultraviolet (EUV) lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources; X-ray, which formally includes EUV at the lower energy range of the X-ray range; as well as e-beam, which can cover a wide energy range. Such methods include those where a substrate, having exposed hydroxyl groups, is contacted with a hydrocarbyl-substituted tin capping agent to form a hydrocarbyl-terminated tin oxide (SnOx) film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology.

EUV lithography—typically at a wavelength of 13.5 nm—is considered as the next enabling technology for lithographic patterning. However, a number of technological stumbling blocks have delayed the widespread introduction and implementation of this technique. EUV photoresist (PR) is one of the roadblocks.

Traditional chemically amplified resist (CAR) provides a cost-effective approach. But organic polymer CARs generate line edge roughness (LER) and line width roughness (LWR), and have sensitivity and resolution limitations due to random fluctuation of the use of polymer. Recent research and development efforts have focused on new EUV inorganic photoresist platform development. Such systems offer several advantages compared to a polymer-based CAR system. These inorganic photoresists are generally based on metal oxides, including metal hydroxide oxides. The small metal oxide molecule size enhances ultimate resolution of the patterning step, and metal oxide photoresists generally show higher etch resistance than CAR, which can reduce PR thickness to reduce structure aspect ratio.

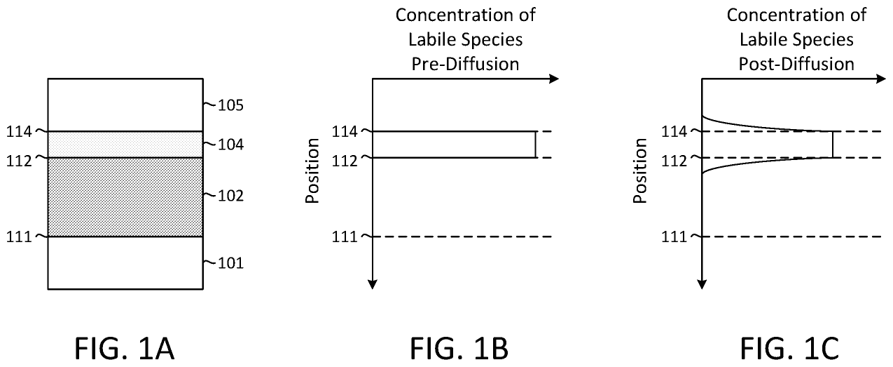

FIG. 1A depicts a substrate 101 having a stack of materials thereon. The substrate may include additional layers as desired for a particular purpose. For instance, the substrate can be or include an amorphous hydrogenated carbon, silicon oxide, silicon nitride, silicon oxynitride, silicon carbide, silicon boronitride, amorphous silicon, polysilicon, or a combination of any described herein, in any form (e.g., a bulk film, a thin film, another film, a stack, etc.). In many cases, the substrate is a partially fabricated semiconductor device, fabricated in any suitable way. As shown in FIG. 1A, the stack includes hardmask 102, underlayer 104, and radiation-sensitive imaging layer 105. The radiation-sensitive imaging layer 105 is often referred to as the photoresist.

The hardmask 102 may have a variety of compositions, such as SiO₂, silicon nitride, and/or an ashable hardmask material. In some cases the hardmask 102 may be silicon carbide. Doped versions of these materials may be used in some cases. The hardmask 102 may be formed by chemical vapor deposition (CVD), for example plasma enhanced CVD (PECVD). Other deposition techniques such as atomic layer deposition (ALD), plasma enhanced ALD (PEALD), or reactive physical vapor deposition (PVD) may be used in some cases. Ashable hardmasks composed of amorphous carbon films are desirable in some implementations. Amorphous carbon films in this context may be undoped, or they may be or doped with boron (B) or tungsten (W), for example. Suitable amorphous carbon films may have a composition including about 50 to 80 atomic % carbon (C), 10 to 20 atomic % hydrogen (H), and 5 to 40 atomic % B or W dopant, for example. The hardmask 102 may have a minimum thickness of about 10 nm, or about 20 nm, or about 50 nm. In these or other cases, the hardmask 102 may have a maximum thickness of about 1 micron, or about 500 nm, or about 100 nm.

The underlayer 104 may be or include a hydrogen-containing carbon film doped with oxygen (O), silicon (Si), nitrogen (N), tungsten (W), boron (B), iodine (I), chlorine (Cl), or a combination of any of these (e.g., a combination of Si and O). The underlayer 104 may be configured to increase adhesion between the hardmask 102 and a subsequently formed radiation-sensitive imaging layer 105, and to reduce EUV dose for effective EUV exposure of the radiation-sensitive imaging layer. In many embodiments, the underlayer is deposited through vapor-base techniques such as CVD, in some cases PECVD. Other deposition techniques such as ALD, PEALD, physical vapor deposition (PVD), and wet methods such as spin-on deposition may be used in some cases. In some embodiments, the underlayer deposition process can be integrated as a termination step during deposition of the hardmask 102. In one embodiment, the underlayer 104 is deposited by introducing or delivering a hydrocarbon precursor (e.g., to provide carbon atoms) and a dopant precursor (e.g., to provide the doping, non-carbon atoms). In another embodiment, the film is deposited by introducing or delivering a heteroatom-containing precursor, such as an iodine-containing precursors, that provides a doped film after deposition. In particular, a hydrogen-containing carbon film doped with iodine can improve generation of secondary electrons upon exposure to EUV radiation. Other types of precursors and/or dopants can be used as desired for particular applications. The underlayer 104 may have a minimum thickness of about 2 nm, or about 5 nm, or about 10 nm, or about 15 nm. The underlayer 104 may have a maximum thickness of 25 nm, or about 20 nm, or about 15 nm, or about 10 nm, or about 5 nm. In many cases, the underlayer 104 may have a thickness between about 2-20 nm. In various cases, the underlayer may include about 0-30 atomic % O and/or about 20-50 atomic % hydrogen (H) and/or 30-70 atomic % C. The underlayer 104 includes one or more labile species, as discussed below in relation to FIGS. 1B and 1C.

Further details related to the underlayer 104 are discussed in International Patent Application No. PCT/US2021/012953, filed Jan. 11, 2021, published as WO2021/146138, and titled “UNDERLAYER FOR PHOTORESIST ADHESION AND DOSE REDUCTION,” which is incorporated by reference herein in its entirety.

Returning to the embodiment of FIG. 1A, the stack of materials further includes radiation-sensitive imaging layer 105. The radiation-sensitive imaging layer 105 can include an EUV-sensitive inorganic photoresist, for example. A suitable EUV-sensitive inorganic photoresist may be a metal oxide film, such as an EUV-sensitive tin oxide-based photoresist. Such resists (also referred to as imaging layers) and their formation and use are described, for example, in International Patent Applications PCT/US2019/031618, filed May 9, 2019, published as WO2019/217749, and titled METHODS FOR MAKING EUV PATTERNABLE HARD MASKS; and PCT/US2019/060742, filed Nov. 11, 2019, published as WO2020/102085, and titled METHODS FOR MAKING HARD MASKS USEFUL IN NEXT GENERATION LITHOGRAPHY, the disclosure of which relating to the composition, deposition, and patterning of directly photopatternable metal-organic based metal oxide films to form EUV resist masks is incorporated by reference herein. As described therein, according to various embodiments, the radiation-sensitive inorganic photoresist may be a spin-on film (e.g., deposited using wet techniques) or a vapor deposited film (e.g., deposited using dry techniques). In cases where vapor deposition is used, the radiation-sensitive imaging layer 105 may be formed through various techniques such as CVD, PECVD, ALD, PEALD, self-assembled monolayer (SAM), or through wet techniques such as spin-on deposition. In some embodiments, the radiation-sensitive imaging layer 105 may be another type of imaging layer, such as a traditional CAR or other type of photoresist, which may likewise be formed through any of the dry or wet deposition methods mentioned above.

In some embodiments, the radiation-sensitive imaging layer 105 is a metaloxy polymer photoresist. In many such cases, the photoresist structure includes a metal atom surrounded by one or more radiolysable ligands. The cleaved metal atoms crosslink in the photoresist structure (e.g., after exposure to patterning radiation), aided by the labile species that emanate from the underlayer 104. As mentioned, other types of photoresist may be used in some cases.

In many cases the radiation-sensitive imaging layer 105 is a polymeric and/or polymerizable material. The radiation-sensitive imaging layer 105 may include one or more material that is photopolymeric, photodecomposing, and/or photocrosslinking. In various embodiments, the radiation-sensitive imaging layer 105 may be a positive photoresist or a negative photoresist. One example positive photoresist is diazonaphthoquinone (DNQ)-Novolac photoresist. Example negative photoresists include epoxy-based polymers, for example the SU-8 photoresist, available from Kayaku Advanced Materials of Westborough, MA, off-stoichiometry thiol-enes (OSTE) polymers, available from Mercene Labs of Stockholm, Sweden, and methyl methacrylate. Other example photoresist materials include, but are not limited to, combinations of woven glass and epoxy (e.g., FR-4, FR-5, G-10), cotton paper and epoxy (e.g., FR-6, CEM-1), woven glass and polyester (e.g., CEM-5), etc.

FIG. 1A also depicts the interfaces between the various materials in the stack, for reference. For example, interface 111 is the interface between the substrate 101 and the hardmask 102, interface 112 is the interface between the hardmask 102 and the underlayer 104, and interface 114 is the interface between the underlayer 104 and the radiation-sensitive imaging layer 105.

As mentioned above, the underlayer 104 includes one or more labile species. In many embodiments, the labile species is hydrogen. Other labile species that may be used in various embodiments include, but are not limited to, isotopes of hydrogen (e.g., ²H, also referred to as deuterium and/or ³H, also referred to as tritium), oxygen (e.g., ¹⁶O, ¹⁷O, and/or ¹⁸O), and/or hydroxyl groups (e.g., —OH). Over time and/or upon application of energy, some portion of the labile species begins to migrate out of the underlayer 104. For example, a fraction of the labile species diffuses upward into the radiation-sensitive imaging layer 105, while a fraction of the labile species diffuses downward into the hardmask 102.

FIG. 1B shows the concentration profile of the labile species at different positions within the stack of materials shown in FIG. 1A, prior to any substantial diffusion of the labile species. FIG. 1C shows the concentration profile of the labile species at different positions within the stack of materials shown in FIG. 1A, after the labile species have diffused to some degree. Interfaces 111, 112, and 114, as depicted in FIG. 1A, are also shown in FIGS. 1B and 1C, for reference. As shown in FIG. 1B, prior to diffusion, the labile species is substantially concentrated in the underlayer 104, between interfaces 112 and 114. As shown in FIG. 1C, after diffusion the labile species is also present in the radiation sensitive imaging layer 105 (e.g., above interface 114) and in the hardmask layer 102 (e.g., below interface 112). The concentration of the labile species is highest at interfaces 112 and 114, and drops when moving away from the underlayer 104. Such diffusion may occur upon application of energy and passage of time in the presence of a concentration difference.

Diffusion of the labile species out of the underlayer 104 can be beneficial. For instance, it has been shown that interactions between the underlayer 104 and the radiation-sensitive imaging layer 105 provide a reduction in DtS. This means that the same or improved imaging results can be achieved with less radiation than would otherwise be required if the underlayer 104 were absent. Without wishing to be bound by theory or mechanism of action, diffusion of labile species (e.g., hydrogen or others) provides one possible mechanism for promoting interactions between (i) the labile species originating from the underlayer 104 and (ii) metal atoms (or other species) within the radiation-sensitive imaging layer 105.

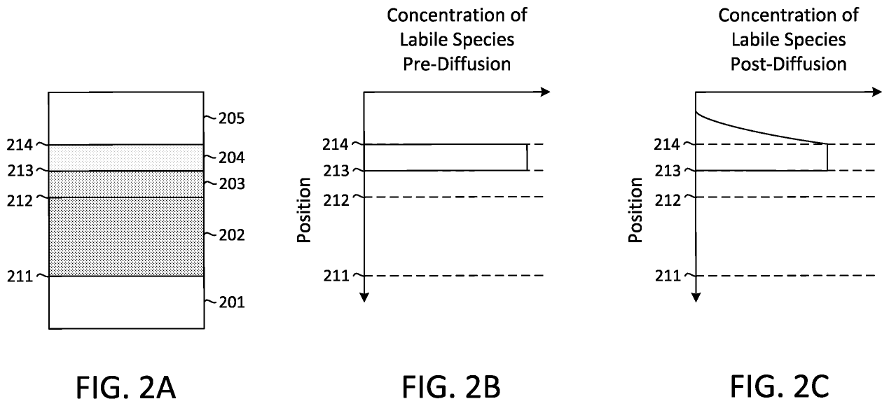

While diffusion of the labile species from the underlayer 104 upward into the radiation-sensitive imaging layer 105 is beneficial, diffusion of such species downward into the hardmask 102 is not. As such, a diffusion barrier layer can be provided between the underlayer 104 and the hardmask 102, as shown in FIG. 2A.

FIG. 2A depicts a substrate 201 having a stack of materials thereon according to various embodiments herein. The stack of materials includes hardmask 202, diffusion barrier layer 203, underlayer 204, and radiation-sensitive imaging layer 205. The substrate may include additional layers as desired for a particular purpose. Generally, hardmask 202 is analogous to hardmask 102, underlayer 204 is analogous to underlayer 104, and radiation-sensitive imaging layer 205 is analogous to radiation-sensitive imaging layer 105. Unless otherwise provided, details related to any of the layers in the embodiment of FIG. 1A may also apply to the analogous layers in the embodiment of FIG. 1B. For the sake of brevity, such details will not be repeated here.

The diffusion barrier layer 203 may include a variety of compositions. For example, the diffusion barrier layer 203 may include an oxide material, a nitride material, a carbide material, silicon, a silicide material, a sulfide material, a metal-containing material, or a combination thereof. In various cases where the diffusion barrier layer 203 includes an oxide material, the oxide may be or include a metal oxide, a silicon oxide, a metal oxynitride, a silicon oxynitride, a metal oxycarbide, a silicon oxycarbide, or a combination thereof. In various cases where the diffusion barrier layer 203 includes a metal (e.g., in the form of a metal oxide, metal oxynitride, metal oxycarbide, etc.), the metal may be selected from the group consisting of aluminum, titanium, molybdenum, tungsten, tin, or a combination thereof. In various cases where the diffusion barrier layer 203 includes a nitride material, the nitride may be or include a metal nitride, a silicon nitride, a metal oxynitride, a silicon oxynitride, or a combination thereof. In various cases where the diffusion barrier layer 203 includes a metal (e.g., in the form of a metal nitride or metal oxynitride), the metal may be selected from the group consisting of aluminum, titanium, molybdenum, tungsten, tin, or a combination thereof. In various embodiments where the diffusion barrier layer 203 includes a carbide material, the carbide may be or include a metal carbide, a silicon carbide, a metal oxycarbide, a silicon oxycarbide, or a combination thereof. In cases where the diffusion barrier layer 203 includes a metal (e.g., in the form of a metal carbide or metal oxycarbide), the metal may be selected from the group consisting of aluminum, titanium, molybdenum, tungsten, tin, or a combination thereof. The diffusion barrier layer 203 may be undoped in some embodiments. In other embodiments, the diffusion barrier layer 203 may be doped with one or more dopants. Example dopants include, but are not limited to, oxygen and nitrogen. In a particular embodiment, the diffusion barrier layer 203 is silicon carbide. In another particular embodiment, the diffusion barrier layer 203 is silicon carbide doped with oxygen. In another particular embodiment, the diffusion barrier layer 203 is silicon carbide doped with nitrogen. In yet another particular embodiment, the diffusion barrier layer 203 is silicon carbide doped with nitrogen and oxygen.

The diffusion barrier layer 203 may be formed in a number of ways. In many cases, a vapor-based deposition technique is used. Example techniques include CVD, PECVD, ALD, PEALD, PVD etc. In other cases, wet deposition techniques may be used, such as spin-on deposition. In certain embodiments, the diffusion barrier layer 203 may have a particular thickness. For example, the diffusion barrier layer may have a minimum thickness of about 3 nm, or about 5 nm, or about 10 nm, or about 20 nm. In these or other embodiments, the diffusion barrier layer may have a maximum thickness of about 100 nm, or about 75 nm, or about 50 nm, or about 10 nm. The thickness of the diffusion barrier layer 203 will depend on the material that is used for this layer. For example, as discussed below with reference to the experimental results of Table 1, a 100A thick diffusion barrier layer of aluminum oxide performed better than a 250A thick diffusion barrier layer of nitrogen-doped silicon carbide at the same conditions. As such, it is believed that metal-containing diffusion barrier layers may be effective at smaller thicknesses than other types of diffusion barrier layers such as those that contain silicon.

Deposition conditions for forming the diffusion barrier layer 203 will vary depending on, e.g., the material of the diffusion barrier layer 203 and the technique being used for deposition. Example deposition temperatures may be as low as about 50° C. or 375° C., and/or as high as about 300° C. or 400° C. Example deposition pressures may be as low as about 5 mTorr or about 900 mTorr, and/or as high as about 1 Torr or about 300 Torr. In cases where plasma is used, various types of plasma may be used including but not limited to capacitively coupled plasma, inductively coupled plasma, and transformer coupled plasma. The plasma may be generated at one or more frequency, such as 13.56 MHz and/or 27 MHz. The plasma may be generated at a particular power level. This power level may be a minimum of about 10 W or about 90 W. In these or other cases, the power level may be a maximum of about 100 W or about 10 kW. These power levels refer to the power provided to process a single 300 mm diameter substrate, and can be scaled linearly based on substrate surface area for substrates of other sizes. Where plasma is used, the plasma may be continuous or pulsed (e.g., at a frequency as low as about 1 Hz and as high as about 10 kHz), with a duty cycle as low as about 1% and as high as about 99%. In some cases a bias may be applied to the substrate during deposition, for example to control ion energy or other factors. Such bias may be similarly continuous or pulsed.

The precursors used to form the diffusion barrier layer 203 can include any combination of precursors that result in formation of the materials listed with respect to the diffusion barrier layer 203. For instance, in cases where the diffusion barrier layer 203 includes an oxide material, an oxygen-containing precursor is provided. Likewise, where the diffusion barrier layer 203 includes a nitride material, a nitrogen-containing precursor is provided; where the diffusion barrier layer 203 includes a carbide material, a carbon-containing precursor is provided; where the diffusion barrier layer 203 includes a metal, a metal-containing precursor is provided; where the diffusion barrier layer 203 includes silicon or a silicide material, a silicon-containing precursor is provided; where the diffusion barrier layer 203 includes a sulfide material, a sulfur-containing precursor is provided. Such precursors can be combined as desired for a particular application.

The diffusion barrier layer 203 may have particular properties in various embodiments. Because the diffusion barrier layer 203 is provided primarily to minimize diffusion in a particular direction, the diffusion barrier layer 203 should be effective in preventing or reducing migration of the labile species at the relevant processing conditions. As mentioned above, in many cases the labile species is hydrogen. In such cases, the diffusion barrier 203 layer should be effective in reducing the migration of hydrogen from the underlayer 204 into the hardmask 202. Diffusion of labile species in the embodiment of FIG. 2A is discussed further below with reference to FIGS. 2B and 2C.

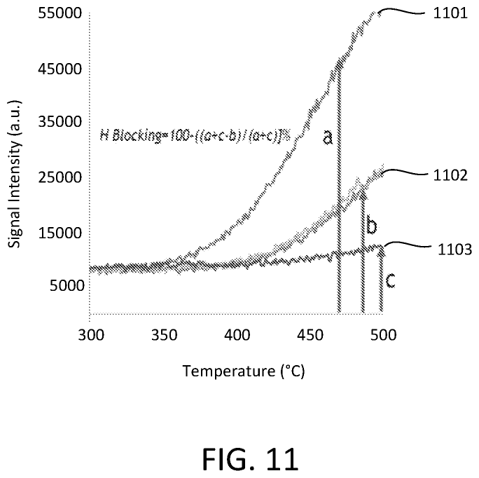

Experimental results showing the effectiveness of certain materials as diffusion barrier layers in reducing diffusion of a labile species are discussed below in relation to FIG. 11, Formula 1, and Table 1. In various embodiments, the diffusion barrier layer is effective in reducing diffusion of labile species (e.g., hydrogen and/or others) by at least about 60%, at least about 70%, at least about 80%, at least about 90%, or at least about 95%. This reduction in diffusion (H_{blocking}) can be calculated according to Formula 1, discussed further below. The reduction in diffusion values provided here may apply at particular temperatures, for example at temperatures of about 100° C., 200° C., 300° C., 350° C., 400° C., 450° C., about 500° C., or between any two of such temperatures.

The diffusion barrier layer 203 should also be compatible with its neighboring materials in the stack on the substrate. This helps avoid unwanted reactions and helps maintain high quality results. This compatibility should apply with respect to both composition and processing conditions. With regard to processing conditions, for instance, certain hardmask materials have a temperature limit and/or thermal budget that should not be exceeded. In various embodiments, an amorphous carbon hardmask should not be subjected to temperatures above about 360° C. In such embodiments, the temperature at which the diffusion barrier layer 203 is formed should be at or below about 360° C.

In various embodiments, the diffusion barrier layer 203 has an amorphous morphology. Such morphology may promote high quality pattern transfer through the relevant layers.

The diffusion barrier layer 203 should also have a composition that can be etched with high selectivity using appropriate chemistry that is compatible with the rest of the materials in the stack, as needed. Relatedly, the diffusion barrier layer 203 should be compatible with the etch chemistry used to transfer the pattern between the diffusion barrier layer 203 and its neighboring layers. In many cases, halide-containing etch chemistry may be used to transfer the pattern between relevant layers in the stack on the substrate. Example halide-containing etch chemistries include fluorine-containing etch chemistry (e.g., CF₄, CHF₃, CH₃F, CH₂F₂, C₄Fg, HF, N₃, and SF₆, etc.), bromine-containing etch chemistry (e.g., BCl₃, etc.) and chlorine-containing etch chemistry (e.g., Cl₂, HCl, BCl₃, etc.).

In some cases, the diffusion barrier layer 203 may have a particular density. Example minimum densities include, e.g., about 1 g/cm³, or about 2 g/cm³. Example maximum densities include, e.g., about 10 g/cm³, or about 5 g/cm³.

Another consideration that may affect the choice of material for the diffusion barrier layer 203 is cost. Various embodiments may favor materials that are relatively less expensive, for example because they can be fabricated using commonly available or easily manufacturable ingredients. Similarly, certain embodiments may favor materials/ingredients that are relatively safer to work with.

In various embodiments, the diffusion barrier layer 203 is deposited as a homogenous layer. In some other embodiments, the diffusion barrier layer 203 may be deposited as a non-homogeneous layer. For instance, it may be deposited to include a gradient in one or more component (e.g., oxygen, nitrogen, carbon, silicon, metal, sulfur, or a material including any one or more of these elements). In some embodiments, the diffusion barrier layer 203 may be deposited as two or more layers, each independently having any of the diffusion barrier layer compositions described herein. As mentioned above, in some cases the diffusion barrier layer 203 is doped. Such doping may be homogeneous or graded (e.g., in a direction perpendicular to the layers, with either a higher or lower concentration of dopants near interface 212 compared to interface 213). In cases where the diffusion barrier layer 203 includes two or more layers, the doping may be present in some or all of these layers. In particular examples, the doping may be confined to an uppermost or lowermost layer of the diffusion barrier layer 203.

FIG. 2B shows the concentration profile of the labile species at different positions within the stack of materials shown in FIG. 2A, prior to any substantial diffusion of the labile species. FIG. 2C shows the concentration profile of the labile species at different positions within the stack of materials shown in FIG. 2A, after the labile species have diffused to some degree. Interfaces 211, 212, 213, and 214, as depicted in FIG. 2A, are also shown in FIGS. 2B and 2C, for reference. As shown in FIG. 2B, prior to diffusion, the labile species is substantially concentrated in the underlayer 204, between interfaces 213 and 214. As shown in FIG. 2C, after diffusion the labile species is also present in the radiation sensitive imaging layer 205 (e.g., above interface 214). Within the radiation sensitive imaging layer 205, the concentration of the labile species is highest at interface 214, and drops when moving away from the underlayer 204. Such diffusion may occur upon application of energy and/or passage of time.

Notably, FIG. 2C shows that after diffusion, there is little to no labile species present in the diffusion barrier layer 203 (e.g., between interfaces 212 and 213) or in the hardmask 202 (e.g., below interface 212). The presence of the diffusion barrier layer 203 substantially reduces or avoids diffusion of the labile species from the underlayer 204 downwards into the diffusion barrier layer 203 and into the hardmask 202. As a result, there is a higher degree of labile species that migrate from the underlayer 204 upwards into the radiation-sensitive imaging layer 205. As compared to FIG. 1C, FIG. 2C shows relatively greater diffusion of the labile species into the radiation-sensitive imaging layer 105/205. As mentioned above, this migration of the labile species into the radiation-sensitive imaging layer 205 is beneficial at least because it results in a lower DtS than would otherwise be required without the presence of the diffusion barrier layer 203.

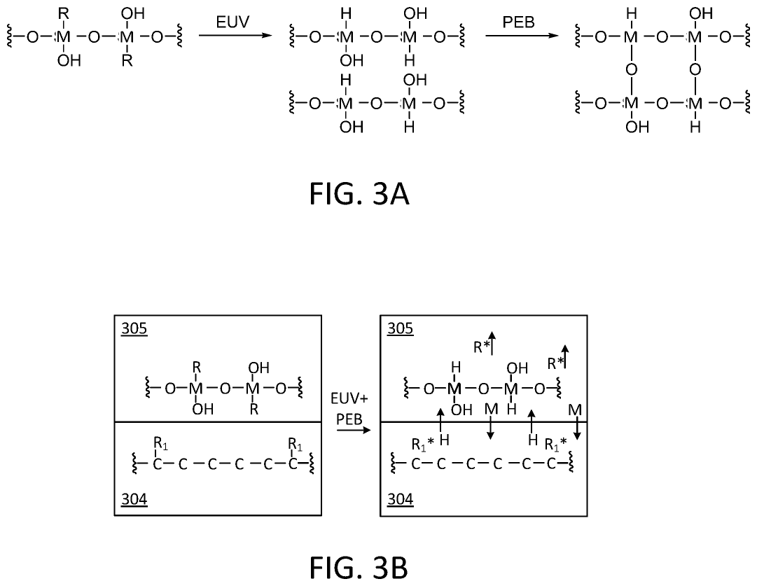

FIGS. 3A and 3B illustrate desirable reactions between an underlayer and a radiation-sensitive imaging layer. These reactions are promoted by diffusion of labile species from the underlayer into the radiation-sensitive imaging layer, and from the radiation-sensitive imaging layer into the underlayer. The use of a diffusion barrier layer below the underlayer further increases the amount of diffusion of labile species upward into the radiation-sensitive imaging layer, as described above.

Possible interactions shown in FIGS. 3A and 3B include migration (or diffusion) of metal (M) atoms from the imaging layer 305 into the underlayer 304; and/or migration (or diffusion) of labile species (e.g., in this example hydrogen (H) atoms) from the underlayer 304 into the radiation-sensitive imaging layer 305. Without wishing to be limited by mechanism, such migration events can provide productive interactions between the underlayer and the imaging layer, which in turn can contribute to improved adhesion and/or DtS.

In addition, the composition of the underlayer and the imaging layer can be designed to promote favorable reactions, which in turn can improve DtS. For instance, as seen in FIG. 3A the imaging layer can include a tin-based photoresist having a radiation-cleavable ligand (R). Upon exposure to radiation (e.g., EUV), the ligand is eliminated from the metal center (e.g., tin center in many cases), and a M-H bond (e.g., Sn—H bond) is formed in its place. After a post-exposure bake (PEB) step, the M-H bonds participate in further thermally-activated crosslinking reactions, thereby increasing material property differences between exposed and unexposed photoresist.

Thus, in one instance, as seen in FIG. 3B, the underlayer 304 can include ligands (R₁) that provide releasable labile species (e.g., H atoms or other labile species), upon exposure to EUV radiation, thereby forming a reacted ligand (R₁*). Possible R₁ groups include, e.g., an optionally substituted alkyl that can be linear or branched. In the radiation-sensitive imaging layer 305, the EUV-cleavable ligand R will provide an eliminated ligand R* and a reactive metal center (M, e.g., Sn). The released labile species (e.g., H atoms) from the underlayer 304 can facilitate formation of the bond within the radiation-sensitive imaging layer 305, the bond being between the metal from the radiation-sensitive imaging layer 305 and the labile species from the underlayer 304 (e.g., an M-H bond such as an Sn—H bond in this example), thereby reducing DtS. If the underlayer 304 also includes oxygen (O) atoms, then such atoms can form M-O bonds (e.g., Sn—O bonds) in the radiation-sensitive imaging layer 305, which can further reduce DtS. Furthermore, metal atoms (e.g., Sn atoms) from the radiation-sensitive imaging layer 305 can diffuse into the underlayer 304, thereby allowing for the generation of additional secondary electrons.

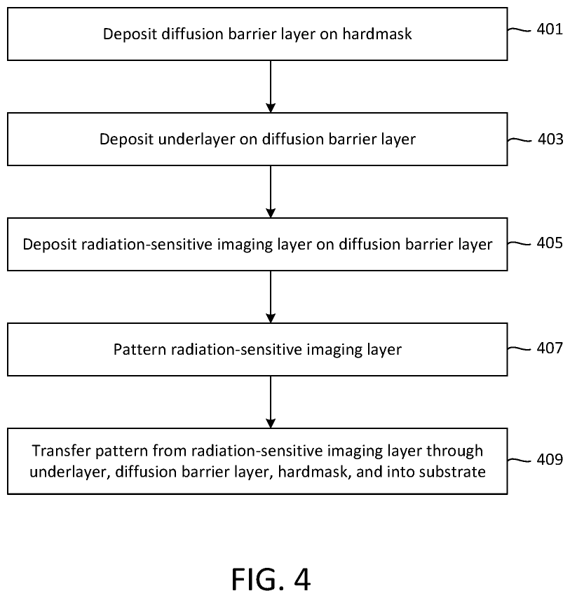

FIG. 4 provides a flowchart describing a method of processing a partially fabricated semiconductor device in accordance with various embodiments. This method may be practiced in the context of a patterning application, for example to define and etch a pattern into the surface of a substrate. The method will be described with reference to the structure shown in FIG. 2A. Any of the details provided above with respect to the structure shown in FIG. 2A (and the analogous layers in FIG. 1A) may apply when practicing the method of FIG. 4. Likewise, any of the details provided with respect to FIGS. 3A and 3B may also apply when practicing the method of FIG. 4. The method of FIG. 4 begins with operation 401, where a diffusion barrier layer 203 is deposited on a hardmask 202.

Next, at operation 403, an underlayer 204 is deposited on the diffusion barrier layer 203. Then, at operation 405, a radiation-sensitive imaging layer 205 is deposited on the underlayer 204. At this point, the stack of materials on the substrate 201 is complete, and the substrate 201 can be processed using photolithography. At operation 407 the radiation-sensitive imaging layer 205 is patterned, for example by selectively exposing the radiation-sensitive imaging layer 205 to radiation, and then developing the pattern by selectively etching either the exposed or unexposed portions of the radiation-sensitive imaging layer 205. Development may occur through dry techniques, wet techniques, or a combination thereof.

Although not shown in FIG. 4, one or more additional operations may take place to promote high quality pattern formation/transfer. Such operations commonly include baking the substrate at elevated temperatures, in some cases under controlled atmospheres. One such operation is referred to as a post application bake (PAB), which may occur after the radiation-sensitive imaging layer is deposited in operation 405 and before the radiation-sensitive imaging layer is exposed to radiation in operation 407. Another such operation is referred to as a post exposure bake (PEB), which may occur after the radiation-sensitive imaging layer is exposed to radiation in operation 407. Another such operation is referred to as a post development bake (PDB), which may occur after the radiation-sensitive imaging layer is developed following exposure to radiation in operation 407. Certain chemical changes that may occur during baking operations are further described in relation to FIGS. 3A and 3B, above.

In the case of post-application processing (e.g., PAB), a thermal process with control of temperature, gas ambient (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide or other materials in the radiation-sensitive imaging layer 205. The change can increase the EUV sensitivity of the material and thus lower DtS and edge roughness can be achieved after exposure and development. In the case of post-exposure processing (e.g., PEB), a thermal process with control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed portions of the radiation-sensitive imaging layer 205. The change can increase the composition/material properties difference between the unexposed and exposed materials and the etch rate difference of dry development etch gas between the unexposed and exposed materials. A higher etch selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂. In the case of post-development processing (e.g., PDB), a thermal process with control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the remaining portions of the radiation-sensitive imaging layer 205. In particular embodiments, the PDB also includes use of plasma (e.g., including O₂, O₃, Ar, He, or their mixtures). The PDB can increase the hardness of material, which can be beneficial if the film will be used as a resist mask when etching the underlying substrate. In various cases, in alternative implementations, the thermal processes described here could be replaced by a remote plasma process to increase reactive species to lower the energy barrier for the reaction and increase productivity. Remote plasma can generate more reactive radicals and therefore lower the reaction temperature/time for the treatment, leading to increased productivity.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

Returning to the embodiment of FIG. 4, at operation 409, the pattern formed in the radiation-sensitive imaging layer is transferred through the underlayer 204, diffusion barrier layer 203, hardmask 202, and into the substrate 201. One or more etching processes may take place in order to transfer the pattern as desired through the relevant layers. In many embodiments, plasma-based etching operations are used.

Related embodiments may include substantially fewer steps. For example, one embodiment includes operation 401 (e.g., deposition of the diffusion barrier layer), without any other steps. Other embodiments may include operation 401 in combination with any one or more of the other steps described in relation to FIG. 4.

### APPARATUS

The present disclosure also includes any apparatus configured to perform any methods described herein. In one embodiment, the apparatus for depositing a film includes a deposition module comprising a chamber for depositing one or more precursor(s) to provide a hardmask, a diffusion barrier layer, an underlayer, and/or an imaging layer; a patterning module comprising an EUV photolithography tool with a source of sub-30 nm wavelength radiation; and a development module comprising a chamber for developing a film including such layers.

The apparatus can further include a controller having instructions for such modules. In one embodiment, the controller includes one or more memory devices, one or more processors, and system control software coded with instructions for conducting deposition of the film. These can include instructions for, in the deposition module, depositing one or more precursor(s) to provide a diffusion barrier layer, an underlayer, and/or an imaging layer; in the patterning module, patterning the layer(s) with sub-30 nm resolution directly by EUV exposure, thereby forming a pattern within the film; and in the development module, developing the film. In particular embodiments, the development module provides for removal of the EUV exposed or EUV unexposed area(s), thereby providing a pattern within the film.

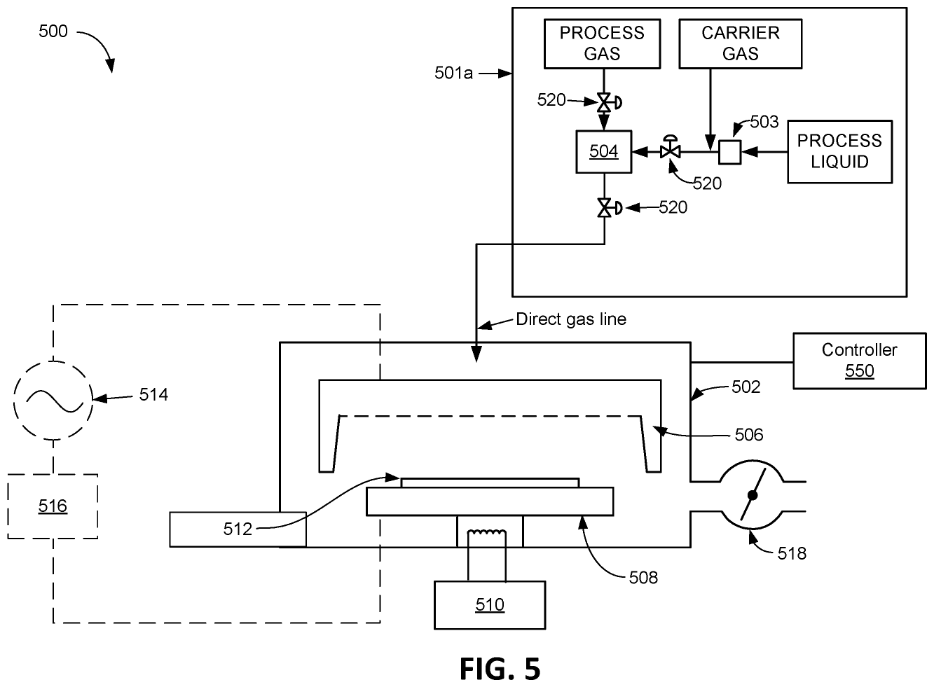

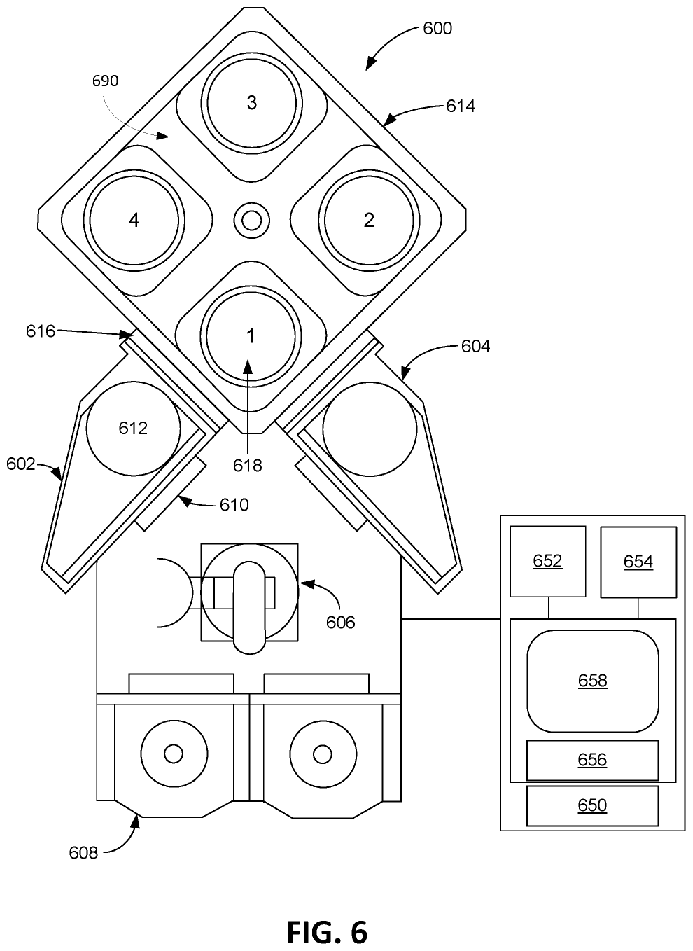

FIG. 5 depicts a schematic illustration of an embodiment of process station 500 having a process chamber body 502 for maintaining a low-pressure environment that is suitable for implementation of described vapor deposition and dry development embodiments as described herein. A plurality of process stations 500 may be included in a common low-pressure process tool environment. For example, FIG. 6 depicts an embodiment of a multi-station processing tool 600. In some embodiments, one or more hardware parameters of the process station 500 including those discussed in detail below may be adjusted programmatically by one or more computer controllers 550.

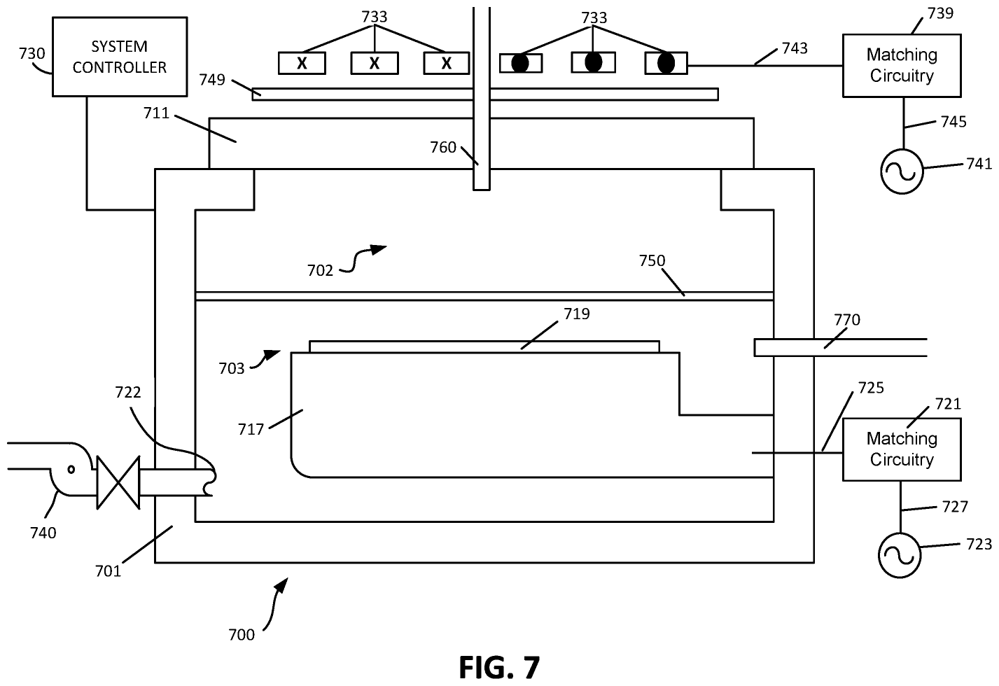

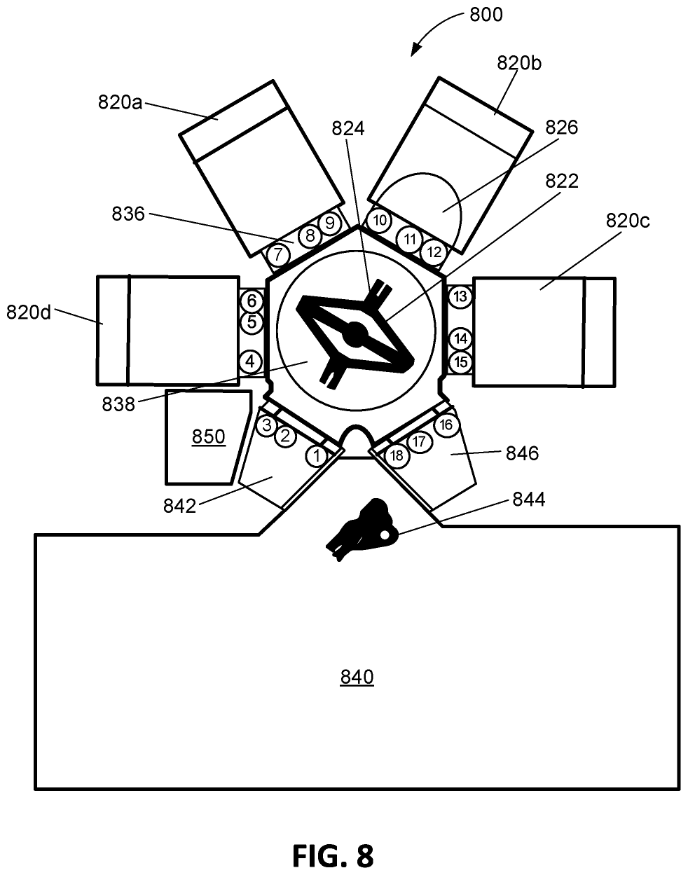

A process station may be configured as a module in a cluster tool. FIG. 8 depicts a semiconductor process cluster tool architecture with vacuum-integrated deposition and patterning modules suitable for implementation of the embodiments described herein. Such a cluster process tool architecture can include PR and underlayer deposition, resist exposure (EUV scanner), resist dry development and etch modules, as described above and further below with reference to FIGS. 7 and 8.

In some embodiments, certain of the processing functions can be performed consecutively in the same module, for example vapor deposition (e.g., PECVD), dry development and etch. And embodiments of this disclosure are directed to apparatus for processing a substrate, the apparatus having a process chamber comprising a substrate support, a process gas source connected with the process chamber and associated flow-control hardware, substrate handling hardware connected with the process chamber, and a controller having a processor and a memory. In some implementations, the processer and the memory are communicatively connected with one another, the processor is at least operatively connected with the flow-control and substrate handling hardware, and the memory stores computer-executable instructions for conducting the operations in the methods of making a pattering structure described herein.

For example, the memory may store computer-executable instructions for providing a hardmask disposed on a substrate, for example by chemical vapor deposition (e.g., PECVD). As described above, suitable hardmasks may be amorphous carbon ashable hardmask films, undoped or doped with B or W, for example. The memory may further store instructions for depositing a diffusion barrier layer on the hardmask/substrate. Appropriate diffusion barrier layers are further discussed above.

The memory may further store instructions for depositing an underlayer on the substrate and/or the diffusion barrier layer, where the underlayer is configured to reduce EUV dose for effective EUV exposure of the photoresist, and in some cases to promote adhesion between relevant layers.

The memory may further store instructions for forming an EUV-sensitive inorganic photoresist on the photoresist underlayer. A suitable EUV-sensitive inorganic photoresist may be a metal oxide film, such as a EUV-sensitive tin oxide-based photoresist, such as described above.

Returning to FIG. 5, process station 500 fluidly communicates with reactant delivery system 501a for delivering process gases to a distribution showerhead 506. Reactant delivery system 501a optionally includes a mixing vessel 504 for blending and/or conditioning process gases, for delivery to showerhead 506. One or more mixing vessel inlet valves 520 may control introduction of process gases to mixing vessel 504. Where plasma exposure is used, plasma may also be delivered to the showerhead 506 or may be generated in the process station 500.

FIG. 5 includes an optional vaporization point 503 for vaporizing liquid reactant to be supplied to the mixing vessel 504. In some embodiments, a liquid flow controller (LFC) upstream of vaporization point 503 may be provided for controlling a mass flow of liquid for vaporization and delivery to process station 500. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 506 distributes process gases toward substrate 512. In the embodiment shown in FIG. 5, the substrate 512 is located beneath showerhead 506 and is shown resting on a pedestal 508. Showerhead 506 may have any suitable shape and may have any suitable number and arrangement of ports for distributing process gases to substrate 512.

In some embodiments, pedestal 508 may be raised or lowered to expose substrate 512 to a volume between the substrate 512 and the showerhead 506. It will be appreciated that, in some embodiments, pedestal height may be adjusted programmatically by a suitable computer controller 550.

In some embodiments, pedestal 508 may be temperature controlled via heater 510. In some embodiments, the pedestal 508 may be heated to a temperature of greater than 0° C. and up to 300° C. or more, for example 50 to 120° C., such as about 65 to 80° C., during non-plasma thermal exposure of a photopatterned resist to hydrogen halide dry development chemistry, such as HBr or HCl.

Further, in some embodiments, pressure control for process station 500 may be provided by a butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to the process station 500.

In some embodiments, a position of showerhead 506 may be adjusted relative to pedestal 308 to vary a volume between the substrate 512 and the showerhead 506. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers 550.

Where plasma may be used, for example in gentle plasma-based dry development embodiments and/or etch operations conducted in the same chamber, showerhead 506 and pedestal 508 electrically communicate with a RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are up to about 500 W. Likewise, RF power supply 514 may provide RF power of any suitable frequency. In some embodiments, RF power supply 514 may be configured to control high- and low-frequency RF power sources independently of one another. Examples of low-frequency RF frequencies may include, but are not limited to, frequencies between 50 kHz and 1000 kHz. Examples of high-frequency RF frequencies may include, but are not limited to, frequencies between 1.8 MHz and 2.45 GHz (e.g., about 13.56 MHz). It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas. The RF power supply may be operated at any suitable duty cycle. Examples of suitable duty cycles include, but are not limited to, duty cycles of between about 5% and 90%. Acceptable process pressures are between about 20 mTorr to 5 Torr.

In some examples, RF power can be continuous or pulsed between one or more levels. If pulsed operation is used, pulsing can be performed at a frequency in a range from 1 Hz to 1 MHz. In some examples, chamber pressure is maintained at a predetermined pressure in a range from 5 mTorr to 450 mTorr. In other examples, deposition and treatment are performed at a pressure in a range from 5 mTorr to 150 mTorr. In still other examples, deposition and treatment are performed at a pressure in a range from 5 mTorr to 35 mTorr.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, instructions for a controller 550 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a first reactant and a second reactant for forming a diffusion barrier layer or any of the other layers described herein. In some embodiments, the controller 550 may include any of the features described below with respect to system controller 550 of FIG. 6.

As described above, one or more process stations may be included in a multi station processing tool. FIG. 6 shows a schematic view of an embodiment of a multi station processing tool 600 with an inbound load lock 602 and an outbound load lock 604, either or both of which may include a remote plasma source. A robot 606 at atmospheric pressure is configured to move wafers from a cassette loaded through a pod 608 into inbound load lock 602 via an atmospheric port 610. A wafer is placed by the robot 606 on a pedestal 612 in the inbound load lock 602, the atmospheric port 610 is closed, and the load lock is pumped down. Where the inbound load lock 602 includes a remote plasma source, the wafer may be exposed to a remote plasma treatment to treat a surface in the load lock prior to being introduced into a processing chamber 614. Further, the wafer also may be heated in the inbound load lock 602 as well, for example, to remove moisture and adsorbed gases. Next, a chamber transport port 616 to processing chamber 614 is opened, and another robot (not shown) places the wafer into the reactor on a pedestal of a first station shown in the reactor for processing. While the embodiment depicted in FIG. 6 includes load locks, it will be appreciated that, in some embodiments, direct entry of a wafer into a process station may be provided.

The depicted processing chamber 614 includes four process stations, numbered from 1 to 4 in the embodiment shown in FIG. 6. Each station has a heated pedestal (shown at 618 for station 1), and gas line inlets. It will be appreciated that in some embodiments, each process station may have different or multiple purposes. For example, in some embodiments, a process station may be switchable between dry development and etch process modes. Additionally, or alternatively, in some embodiments, processing chamber 614 may include one or more matched pairs of dry development and etch process stations. While the depicted processing chamber 614 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 6 depicts an embodiment of a wafer handling system 690 for transferring wafers within the processing chamber 614. In some embodiments, wafer handling system 690 may transfer wafers between various process stations and/or between a process station and a load lock. It will be appreciated that any suitable wafer handling system may be employed. Non-limiting examples include wafer carousels and wafer handling robots. FIG. 6 also depicts an embodiment of a system controller 650 employed to control process conditions and hardware states of process tool 600. System controller 650 may include one or more memory devices 656, one or more mass storage devices 654, and one or more processors 652. Processor 652 may include a CPU or computer, analog, and/or digital input/output connections, stepper motor controller boards, etc.

In some embodiments, system controller 650 controls all of the activities of process tool 600. System controller 650 executes system control software 658 stored in mass storage device 654, loaded into memory device 656, and executed on processor 652. Alternatively, the control logic may be hard coded in the controller 650. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 658 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 600. System control software 658 may be configured in any suitable way. For example, various process tool component subroutines or control objects may be written to control operation of the process tool components used to carry out various process tool processes. System control software 658 may be coded in any suitable computer readable programming language.

In some embodiments, system control software 658 may include input/output control (IOC) sequencing instructions for controlling the various parameters described above. Other computer software and/or programs stored on mass storage device 654 and/or memory device 656 associated with system controller 650 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling gas composition (e.g., any precursors, etch gases, or other processing gasses) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 650. The user interface may include a display screen, graphical software displays of the apparatus and/or process conditions, and user input devices such as pointing devices, keyboards, touch screens, microphones, etc.

In some embodiments, parameters adjusted by the system controller 650 may relate to process conditions. Non-limiting examples include process gas composition and flow rates, temperature, pressure, plasma conditions (such as RF bias power levels, frequency, and exposure time), etc. These parameters may be provided to the user in the form of a recipe, which may be entered utilizing the user interface.

Signals for monitoring the process may be provided by analog and/or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 650 may provide program instructions for implementing the above-described deposition processes. The program instructions may control a variety of process parameters, such as direct current (DC) power level, RF bias power level, pressure, temperature, etc. The instructions may control the parameters to operate photoresist underlayer deposition processes according to various embodiments described herein.

The system controller 650 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 650.

In some implementations, the system controller 650 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 650, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 650 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 650 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 650, in some implementations, may be a part of or coupled to a computer that is integrated with, coupled to the system, otherwise networked to the system, or a combination thereof. For example, the system controller 650 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 650 receives instructions in the form of data, which specify parameters for each of the processing steps to be performed during one or more operations. It should be understood that the parameters may be specific to the type of process to be performed and the type of tool that the system controller 650 is configured to interface with or control. Thus, as described above, the system controller 650 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 650 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

FIG. 7 schematically shows a cross-sectional view of an inductively coupled plasma apparatus 700 appropriate for implementing certain embodiments or aspects of embodiments such as vapor (dry) deposition, dry development and/or etch. In other embodiments, other tools or tool types having the functionality to conduct the dry deposition, development and/or etch processes described herein may be used for implementation.

The inductively coupled plasma apparatus 700 includes an overall process chamber 724 structurally defined by chamber walls 701 and a window 711. The chamber walls 701 may be fabricated from stainless steel or aluminum. The window 711 may be fabricated from quartz or other dielectric material. An optional internal plasma grid 750 divides the overall process chamber into an upper sub-chamber 702 and a lower sub chamber 703. In most embodiments, plasma grid 750 may be removed, thereby utilizing a chamber space made of sub chambers 702 and 703. A chuck 717 is positioned within the lower sub-chamber 703 near the bottom inner surface. The chuck 717 is configured to receive and hold a semiconductor wafer 719 upon which the etching and deposition processes are performed. The chuck 717 can be an electrostatic chuck for supporting the wafer 719 when present. In some embodiments, an edge ring (not shown) surrounds chuck 717 and has an upper surface that is approximately planar with a top surface of the wafer 719, when present over chuck 717. The chuck 717 also includes electrostatic electrodes for chucking and dechucking the wafer 719. A filter and DC clamp power supply (not shown) may be provided for this purpose. Other control systems for lifting the wafer 719 off the chuck 717 can also be provided. The chuck 717 can be electrically charged using an RF power supply 723. The RF power supply 723 is connected to matching circuitry 721 through a connection 727. The matching circuitry 721 is connected to the chuck 717 through a connection 725. In this manner, the RF power supply 723 is connected to the chuck 717. In various embodiments, a bias power of the electrostatic chuck may be set at about 50V or may be set at a different bias power depending on the process performed in accordance with disclosed embodiments. For example, the bias power may be between about 20 V and about 100 V, or between about 30 V and about 150 V.

Elements for plasma generation include a coil 733 is positioned above window 711. In some embodiments, a coil is not used in disclosed embodiments. The coil 733 is fabricated from an electrically conductive material and includes at least one complete turn. The example of a coil 733 shown in FIG. 7 includes three turns. The cross sections of coil 733 are shown with symbols, and coils having an “X” extend rotationally into the page, while coils having a “•” extend rotationally out of the page. Elements for plasma generation also include an RF power supply 741 configured to supply RF power to the coil 733. In general, the RF power supply 741 is connected to matching circuitry 739 through a connection 745. The matching circuitry 739 is connected to the coil 733 through a connection 743. In this manner, the RF power supply 741 is connected to the coil 733. An optional Faraday shield 749a is positioned between the coil 733 and the window 711. The Faraday shield 749a may be maintained in a spaced apart relationship relative to the coil 733. In some embodiments, the Faraday shield 749a is disposed immediately above the window 711. In some embodiments, the Faraday shield 749b is between the window 711 and the chuck 717. In some embodiments, the Faraday shield 749b is not maintained in a spaced apart relationship relative to the coil 733. For example, the Faraday shield 749b may be directly below the window 711 without a gap. The coil 733, the Faraday shield 749a, and the window 711 are each configured to be substantially parallel to one another. The Faraday shield 749a may prevent metal or other species from depositing on the window 711 of the process chamber 724.

Process gases may be flowed into the process chamber through one or more main gas flow inlets 760 positioned in the upper sub-chamber 702 and/or through one or more side gas flow inlets 770. Likewise, though not explicitly shown, similar gas flow inlets may be used to supply process gases to a capacitively coupled plasma processing chamber. A vacuum pump, e.g., a one or two stage mechanical dry pump and/or turbomolecular pump 740, may be used to draw process gases out of the process chamber 724 and to maintain a pressure within the process chamber 724. For example, the vacuum pump may be used to evacuate the lower sub-chamber 703 during a purge operation of ALD. A valve-controlled conduit may be used to fluidically connect the vacuum pump to the process chamber 724 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 700, one or more process gases may be supplied through the gas flow inlets 760 and/or 770. In certain embodiments, process gas may be supplied only through the main gas flow inlet 760, or only through the side gas flow inlet 770. In some cases, the gas flow inlets shown in the figure may be replaced by more complex gas flow inlets, one or more showerheads, for example. The Faraday shield 749a and/or optional grid 750 may include internal channels and holes that allow delivery of process gases to the process chamber 724. Either or both of Faraday shield 749a and optional grid 750 may serve as a showerhead for delivery of process gases. In some embodiments, a liquid vaporization and delivery system may be situated upstream of the process chamber 724, such that once a liquid reactant or precursor is vaporized, the vaporized reactant or precursor is introduced into the process chamber 724 via a gas flow inlet 760 and/or 770.

Radio frequency power is supplied from the RF power supply 741 to the coil 733 to cause an RF current to flow through the coil 733. The RF current flowing through the coil 733 generates an electromagnetic field about the coil 733. The electromagnetic field generates an inductive current within the upper sub-chamber 702. The physical and chemical interactions of various generated ions and radicals with the wafer 719 etch features of and selectively deposit layers on the wafer 719.

If the plasma grid 750 is used such that there is both an upper sub-chamber 702 and a lower sub-chamber 703, the inductive current acts on the gas present in the upper sub-chamber 702 to generate an electron-ion plasma in the upper sub-chamber 702. The optional internal plasma grid 750 limits the amount of hot electrons in the lower sub-chamber 703. In some embodiments, the apparatus 700 is designed and operated such that the plasma present in the lower sub-chamber 703 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 703 through port 722. The chuck 717 disclosed herein may operate at elevated temperatures ranging between about 10° C. and about 250° C. The temperature will depend on the process operation and specific recipe.

Apparatus 700 may be coupled to facilities (not shown) when installed in a clean room or a fabrication facility. Facilities include plumbing that provide processing gases, vacuum, temperature control, and environmental particle control. These facilities are coupled to apparatus 700, when installed in the target fabrication facility. Additionally, apparatus 700 may be coupled to a transfer chamber that allows robotics to transfer semiconductor wafers into and out of apparatus 700 using typical automation.

In some embodiments, a system controller 730 (which may include one or more physical or logical controllers) controls some or all of the operations of a process chamber 724. The system controller 730 may include one or more memory devices and one or more processors. In some embodiments, the apparatus 700 includes a switching system for controlling flow rates and durations when disclosed embodiments are performed. In some embodiments, the apparatus 700 may have a switching time of up to about 500 ms, or up to about 750 ms. Switching time may depend on the flow chemistry, recipe chosen, reactor architecture, and other factors.

In some implementations, the system controller 730 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 730, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 730 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 730, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 730 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 730 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (e.g., PECVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 8 depicts a semiconductor process cluster tool architecture 800 with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 8 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 838 interfaces with four processing modules 820a-820d, which may be individually optimized to perform various fabrication processes. By way of example, processing modules 820a-820d may be implemented to perform deposition, lithography operations, evaporation, ELD, dry development, etch, strip, and/or other semiconductor processes. For example, module 820a may be a deposition reactor that may be operated to deposit one or more of the layers shown in FIG. 2A. And module 820b deposition tool that may be operated to deposit one more other layers shown in FIG. 2A, other than those deposited by module 820a. Any number of deposition modules or other modules may be provided. Module 820c may be operated to perform one or more photolithography-related operation such as an exposure operation, a baking operation, a development operation, etc. Module 820d may be operated to perform etching, for example to transfer a pattern from a radiation-sensitive imaging layer to underlying layers. It should be understood that the figure is not necessarily drawn to scale.

Airlocks 842 and 846, also known as a loadlocks or transfer modules, interface with the VTM 838 and a patterning module 840. For example, as noted above, a suitable patterning module may be the TWINSCAN NXE: 3300B@platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, either stand alone or integrated in a cluster architecture with other tools, such as etch, strip etc., as modules, for example as described with reference to FIG. 8 but without the integrated patterning module.

Airlock 842 may be an “outgoing” loadlock, referring to the transfer of a substrate out from the VTM 838 serving a deposition module 820a to the patterning module 840, and airlock 846 may be an “ingoing” loadlock, referring to the transfer of a substrate from the patterning module 840 back in to the VTM 838. The ingoing loadlock 846 may also provide an interface to the exterior of the tool for access and egress of substrates. Each process module has a facet that interfaces the module to VTM 838. For example, deposition process module 820a has facet 836. Inside each facet, sensors, for example, sensors 1-18 as shown, are used to detect the passing of wafer 826 when moved between respective stations. Patterning module 840 and airlocks 842 and 846 may be similarly equipped with additional facets and sensors, not shown.

Main VTM robot 822 transfers wafer 826 between modules, including airlocks 842 and 846. In one embodiment, robot 822 has one arm, and in another embodiment, robot 822 has two arms, where each arm has an end effector 824 to pick wafers such as wafer 826 for transport. Front-end robot 844, in is used to transfer wafers 826 from outgoing airlock 842 into the patterning module 840, from the patterning module 840 into ingoing airlock 846. Front-end robot 844 may also transport wafers 826 between the ingoing loadlock and the exterior of the tool for access and egress of substrates. Because ingoing airlock module 846 has the ability to match the environment between atmospheric and vacuum, the wafer 826 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 842 may provide this function by holding the transferred wafers at a lower pressure, no higher than the pressure in the patterning module 840, for a period of time and exhausting any off-gassing, so that the optics of the patterning tool 840 are not contaminated by off-gassing from the substrate. A suitable pressure for the outgoing, off-gassing airlock is no more than 1E-8 Torr.

In some embodiments, a system controller 850 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 850 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative and/or positive pattern mask is provided. The apparatus may include a processing chamber for patterning, deposition and etch, and a controller including instructions for forming the pattern mask. The instructions may include code for, in the processing chamber, patterning a feature in radiation-sensitive imaging layer on a semiconductor substrate by EUV exposure to expose a surface of the substrate, dry developing the photopatterned resist, and etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network. A controller as described above with respect to any of FIGS. 5, 6, or 7 may be implemented with the tool in FIG. 8.

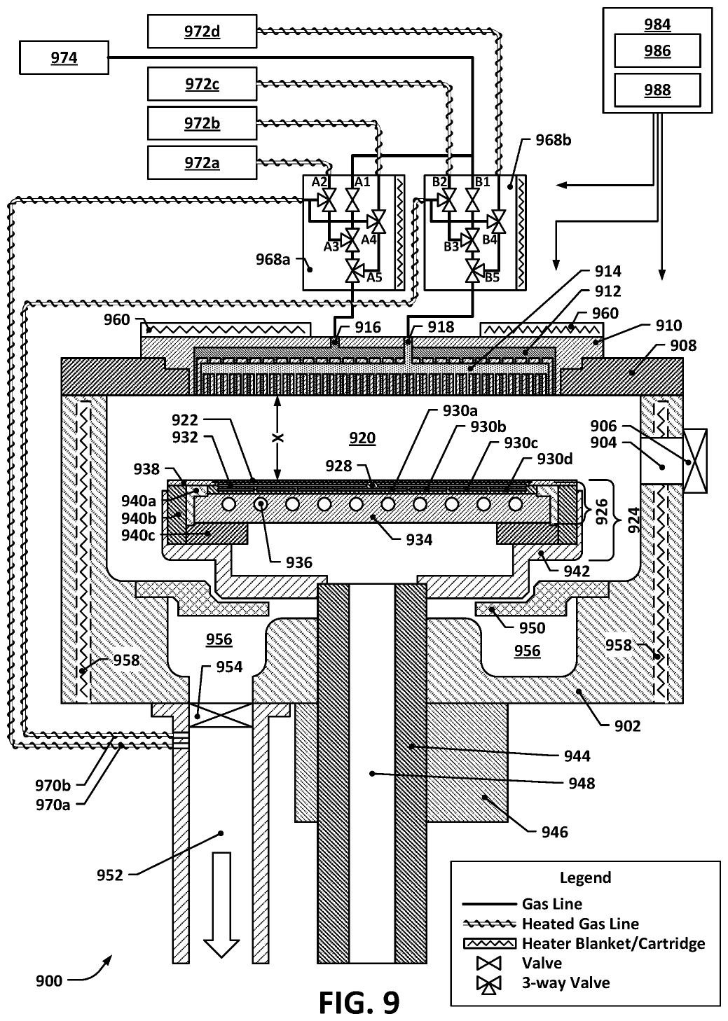

FIG. 9 shows an example of a deposition chamber (e.g., for vapor-based deposition, such as for an imaging layer and/or an under layer). As can be seen, the apparatus 900 includes a processing chamber 902 having a lid 908 and a wafer transfer passage 904, which is sized to allow a substrate 922 to be passed therethrough and to be placed on a wafer support 924. The wafer transfer passage 904 may have a gate valve 906 or similar door mechanism that may be operated to seal or unseal the wafer transfer passage. For example, the processing chamber 902 may be provided substrates 922 via a wafer handling robot that is located in an adjoining transfer chamber.

The wafer support 924 may include an ESC 926 to provide a wafer support surface for the substrate 922. The ESC 926 may include a base plate 934 that is bonded to a top surface of the top plate 928. In the depicted example, the top plate 928 has two separate electrical systems embedded within it. One such system is an electrostatic clamping electrode system having one or more clamping electrodes 932 to generate an electric charge within the substrate 922 that causes the substrate 922 to be drawn against the wafer support surface of the top plate 928.

The other system is a thermal control system to control the temperature of the substrate 922 during processing conditions. In FIG. 9, the thermal control system features four annular resistance heater traces 930a, 930b, 930c, and 930d positioned beneath the clamping electrodes 932. Each resistance heater trace 930a/b/c/d may be individually controlled to provide a variety of radial heating profiles in the top plate 928, for example, to maintain the substrate 922 so as to have a temperature uniformity of 0.5° C. in some cases. Other implementations may use single-zone or multi-zone heating systems having more or fewer than four zones. In some implementations, of, for example, temperature control mechanisms discussed above, heat pumps or Peltier junctions may be used instead of resistance heating traces.

The ESC 926 may also include a base plate 934 to provide structural support to the underside of the top plate 928 and which may also act as a heat dispersion system. For example, the base plate 934 may include one or more heat exchange passages 936; and a heat exchange medium, e.g., water or inert fluorinated liquid, may be circulated through the heat exchange passages 936 during use.

The ESC 926 may be supported by a wafer support housing 942 that is connected with, and supported by, a wafer support column 944. The wafer support column 944 may have a routing passage 948 other pass-throughs for routing cabling (e.g., for providing electrical power), fluid flow conduits (e.g., for conveying heat exchange medium), and other equipment to the underside of the base plate 934 and/or the top plate 928.

The apparatus 900 of FIG. 9 also includes a wafer support z-actuator 946 that may provide movable support to the wafer support column 944. The wafer support z-actuator 946 may be actuated to cause the wafer support column 944, and the wafer support 924 supported thereby, to move up or down vertically, e.g., by up to several inches, within a reaction space 920 of the processing chamber 902. In doing so, a gap distance X between the substrate 922 and the underside of the showerhead 910 may be tuned depending on various process conditions.

The wafer support 924 may also include one or more edge rings that may be used to control and/or fine-tune various process conditions. In FIG. 9, an upper edge ring 938 is provided that lies on top of, for example, lower edge rings 940a and 940b, which, in turn, are supported by the wafer support housing 942 and a third lower edge ring 940c.

The apparatus 900 may also include a system for removing process gases from the processing chamber 902 during and after processing concludes. For example, the processing chamber 902 may include an annular plenum 956 that encircles the wafer support column 944. The annular plenum 956 may, in turn, be fluidically connected with a vacuum foreline 952 that may be connected with a vacuum pump. A regulator valve 954 may be provided in between the vacuum foreline 952 and the processing chamber 902 and actuated to control the flow into the vacuum foreline 952. In some implementations, a baffle 950, e.g., an annular plate or other structure that may serve to make the flow into the annular plenum 956 more evenly distributed about the circumference of the wafer support column 944, may be provided to reduce the chances of flow non-uniformities developing in reactants flowed across the substrate 722.

The showerhead 910, as shown, is a dual-plenum showerhead 910 and includes a first plenum 912 that is provided process gas via a first inlet 916 and a second plenum 914 that is provided process gas via a second inlet 918. Two or more plenums can be employed to maintain separation between the precursor(s) and the counter-reactant(s) prior to release of the precursor and the counter-reactant. In some instances, a single plenum is used to deliver the precursor(s) into the reaction space 920 of the processing chamber 902. Each plenum may have a corresponding set of gas distribution ports that fluidically connect the respective plenum with the reaction space 920 through the faceplate of the showerhead 910 (the faceplate being the portion of the showerhead 910 that is interposed between the lowermost plenum and the reaction space 920).

The first inlet 916 and the second inlet 918 of the showerhead 910 may be provided processing gases via a gas supply system, which may be configured to provide one or more precursor(s) and/or counter-reactant(s), as discussed herein. A first valve manifold 968a may be configured to provide one or more precursor(s) to the first inlet 916, while a second valve manifold 968b may be configured to provide other precursor(s) or other reactant to the second inlet 918. In this example, the first valve manifold 968a, for example, includes multiple valves A1-A5. Valve A2 may, for example, be a three-way valve that has one port fluidically connected with a first vaporizer 972a, another port fluidically connected with a bypass line 970a, and a third port fluidically connected with a port on another 3-way valve A3. Similarly, valve A4 may be another three-way valve that has one port fluidically connected with a second vaporizer 972b, another port fluidically connected with the bypass line 970a, and a third port fluidically connected with a port on another 3-way valve A5. One of the other ports on valve A5 may be fluidically connected with the first inlet 916 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 974, e.g., nitrogen, argon, or other suitably inert gas (with respect to precursor(s) and/or counter-reactant(s)). In some embodiments, only the first valve manifold is employed.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 968a may, for example, be controllable to cause vapors from one or both of the vaporizers 972a and 972b to be flowed either to the processing chamber 902 or through the first bypass line 970a and into the vacuum foreline 952, such as by controlled actuation of valves A1-A5. The first valve manifold 968a may also be controllable to cause a purge gas to be flowed from the purge gas source 974 and into the first inlet 916.

It will be appreciated that the second valve manifold 968b may be controlled in a similar manner, e.g., by controlling valves B1-B5, to provide vapors from vaporizers 972c and 972d to the second inlet 918 or to the second bypass line 970b. It will be further appreciated that different manifold arrangements may be utilized as well, including a single unitary manifold that includes valves for controlling flow of the precursor(s), counter-reactant(s), or other reactants to the first inlet 916 and the second inlet 918.

As mentioned earlier, some apparatuses 900 may feature a lesser number of vapor sources, e.g., only two vaporizers 972, in which case the valve manifold(s) 968 may be modified to have a lesser number of valves, e.g., only valves A1-A3.

As discussed above, apparatuses such as apparatus 900, which may be used to provide for dry deposition of films, may be configured to maintain particular temperature profiles within the processing chamber 902. In particular, such apparatuses 900 may be configured to maintain the substrate 922 at a lower temperature, e.g., at least 25° C. to 50° C. lower, than most of the equipment of the apparatus 902 that comes into direct contact with the precursor(s) and/or counter-reactant(s).

To provide for temperature control, various heating systems may be included in the apparatus 900. For example, the processing chamber 902 may have receptacles for receiving cartridge heaters 958, e.g., vertical holes for receiving cartridge heaters 958 may be bored into the four corners of the chamber 902 housing. In some implementations, the showerhead 910 may be covered with heater blankets 960, which may be used to apply heat across the exposed upper surface of the showerhead 910 to keep the showerhead temperature elevated. It may also be beneficial to heat various gas lines that are used to conduct the vaporized reactants from the vaporizers 972 to the showerhead 910. For example, resistive heater tape may be wound around such gas lines and used to heat them to an elevated temperature. Any of the gas lines and even the fate valve 906 in FIG. 9 can be actively or indirectly heated.

The various operational systems of the apparatus 900 may be controlled by a controller 984, which may include one or more processors 986 and one or more memory devices 988 that are operatively connected with each other and that are communicatively connected with various systems and subsystems of the apparatus 900 so as to provide for control functionality for those systems. For example, the controller 984 may be configured to control the valves A1-A5 and B1-B5, the various heaters 958, 960, the vaporizers 972, the regulator valve 954, the gate valve 906, the wafer support z-actuator, and so forth.

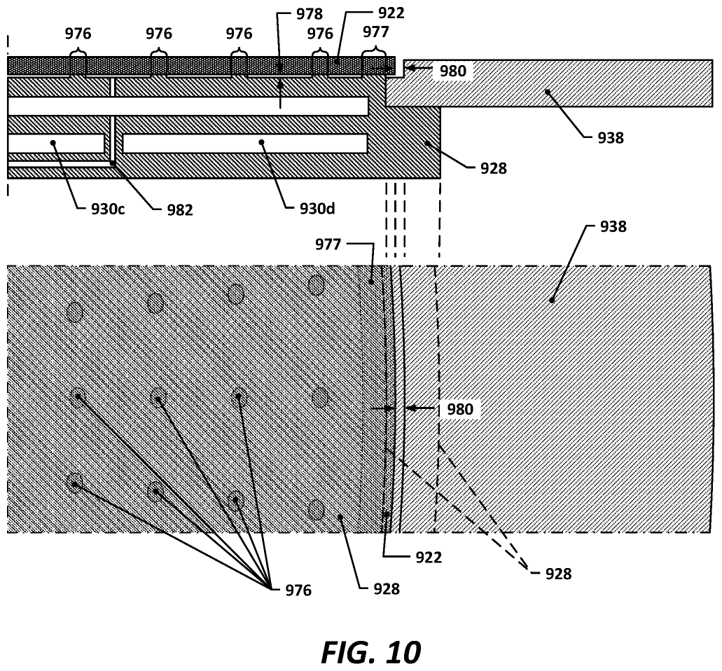

Another feature that the apparatus 900 may include is shown in FIG. 10, which depicts close-up side cross-sectional and plan views of a portion of the substrate 922, top plate 928, and upper edge ring 938 of FIG. 9. As can be seen, in some implementations, the substrate 922 may be elevated off of most of the top plate 928 by a plurality of small mesas 976, which may be shallow bosses that protrude from the nominal upper surface of the top plate 928 by a small distance so as to provide for a backside gap 978 between the underside of the substrate 922 and the majority of the top plate 928. A circumferential wall feature 977 may be provided at the periphery of the top plate 928. The circumferential wall feature 977 may extend around the entire perimeter of the top plate 928 and be of nominally the same height as the mesas 976. During processing operations, a generally inert gas, such as helium, may be flowed into the backside gap 978 via one or more gas ports 982. This gas may then flow radially outward before encountering the circumferential wall feature 977, which way then restrict such radially outward flow and cause a higher-pressure region of the gas to be trapped between the substrate 922 and the top plate 928. The inert gas that leaks past the circumferential wall 977 may eventually flow out through a radial gap 980 between the outer edge of the substrate 922 and a portion of the upper edge ring 938. Such gas may serve to protect the underside of the substrate from undesirably being affected by the processing operations being performed by acting to prevent the gases released by the showerhead 910 from reaching the underside of the substrate 922. At the same time, the gas released into the backside gap 978 region may also act to increase thermal coupling between the substrate 922 and the top plate 928, thereby allowing the top plate 928 to more effectively heat or cool the substrate 922. Due to the higher pressure provided by the circumferential wall, the gas that is within the backside gap 978 region may also be at a higher density than gas in the remainder of the chamber, and may thus provide more effective thermal coupling between the substrate 922 and the top plate 928.

The controller 984 may be configured, e.g., via execution of computer-executable instructions, to cause the apparatus 900 to perform various operations consistent with the disclosure provided above.

Once the imaging layer and/or underlayer has been deposited on the substrate 922, the substrate 922 may, as noted above, be transferred to one or more subsequent processing chambers or tool for additional operations (e.g., any described herein). Further deposition apparatuses are described in International Patent Application No. PCT/US2020/038968, filed Jun. 22, 2020, titled “APPARATUS FOR PHOTORESIST DRY DEPOSITION,” which is herein incorporated by reference in its entirety.

### EXPERIMENTAL

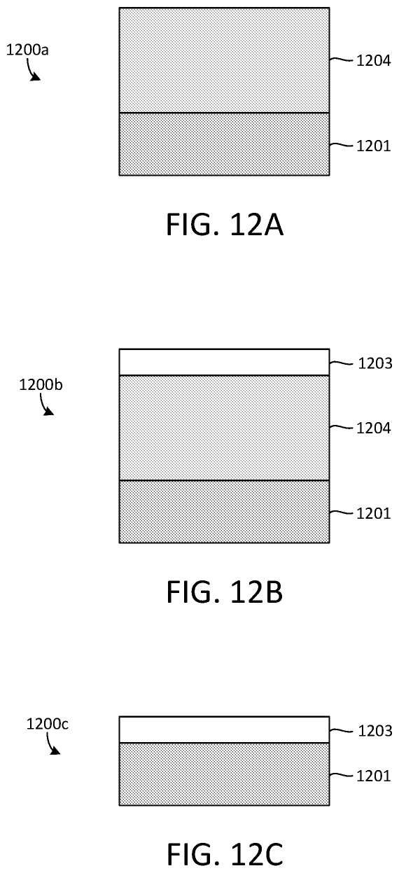

FIG. 11 depicts experimental results showing the effectiveness of a diffusion barrier layer in reducing diffusion of a labile species at different temperatures. In this experiment, the labile species was hydrogen. Three substrates were tested, each having one of the structures shown in FIGS. 12A-12C.

As shown in FIG. 12A, the first substrate 1200a included a layer of low temperature thermally deposited silicon nitride 1204 over a silicon substrate 1201. Low temperature thermally deposited silicon nitride is known to include a substantial amount of hydrogen, which can act as a labile species. The results related to the first substrate 1200a are shown by line 1101 in FIG. 11.

As shown in FIG. 12B, the second substrate 1200b included silicon substrate 1201 and a layer of low temperature thermally deposited silicon nitride 1204, which was capped with a diffusion barrier layer made of nitrogen-doped silicon carbide 1203. The results related to the second substrate 1200b are shown by line 1102 in FIG. 11. It should be understood that although FIG. 12B shows the diffusion barrier layer of nitrogen-doped silicon carbide 1203 positioned over the layer of low temperature thermally deposited silicon nitride 1204, this is merely for the purpose of experimentation and evaluation of diffusion. In various photolithography embodiments described herein, e.g., as described in relation to FIG. 2A, these layers are switched such that the diffusion barrier layer 203 is positioned below the layer from which the labile species originates (e.g., the underlayer 204).

As shown in FIG. 12C, the third substrate 1200c included a layer of nitrogen-doped silicon carbide 1203 over a silicon substrate 1201. The results related to the third substrate 1200c are shown by line 1103 in FIG. 11. Generally, the silicon nitride layers 1204 of the first and second substrates 1200a and 1200b were analogous, and the nitrogen-doped silicon carbide layers 1203 of the second and third substrates 1200b and 1200c were analogous. The silicon nitride layers 1204 had a thickness of about 100 nm, and the nitrogen-doped silicon carbide layers 1203 had a thickness of about 250 Å.

The substrates 1200a-1200c were subjected to heating at different temperatures, and a signal corresponding to the amount of hydrogen in the exposed layer was measured. FIG. 11 shows the different temperatures along the x-axis, and the signal intensity along the y-axis. Generally, a higher signal intensity along the y-axis corresponds to a higher amount of hydrogen in the exposed layer on the substrate.

The data in FIG. 11 can be used to calculate the degree to which a diffusion barrier layer (e.g., the nitrogen-doped silicon carbide layer 1203 in this example) is effective in blocking diffusion of a labile species (e.g., hydrogen in this example) from a first layer (e.g., the silicon nitride layer 1204 in this example) through the diffusion barrier layer at a particular temperature. Formula 1 below provides an example calculation:

$${H}_{blocking} = 100 - 100 * \frac{a + c - b}{a + c} \qquad Formula 1$$

where:
a=signal intensity from substrate having exposed layer from which the labile species originates, without any capping layer (e.g., from the first substrate 1200a of FIG. 12A, corresponding to line 1101 in FIG. 11),
b=signal intensity from substate having diffusion barrier layer exposed over layer from which the labile species originates (e.g., from the second substrate 1200b of FIG. 12B, corresponding to line 1102 in FIG. 11), and
c=signal intensity from substrate having diffusion barrier layer exposed, without any other layer from which the labile species originates (e.g., from the third substrate 1200c of FIG. 12C, corresponding to line 1103 in FIG. 11).

In Formula 1, H_{blocking} is expressed as a percentage, and can be calculated for each temperature that is tested. Although FIG. 11 shows a, b, and c labeled at different temperatures, this is merely for the purpose of illustration. When Hblocking is calculated, the signal intensities are considered at a particular temperature. Moreover, although Formula 1 explicitly relates to H_{blocking}, it should be understood that this same technique can be used to evaluate diffusion of other labile species, as well.

In a related experiment, a series of potential diffusion barrier layers was tested as described in relation to FIG. 11, and the degree of H_{blocking} for each layer was calculated at different temperatures. The thickness of the diffusion barrier layers ranged between about 50-250 Å. Of the different types of diffusion barrier layers that were tested, those that showed the best H_{blocking} performance were aluminum oxide and nitrogen-doped silicon carbide. Table 1 below illustrates the most promising results of this experiment, with results shown at both 450° C. and 500° C.

TABLE 1

| | Film | H_{blocking} at | H_{blocking} at |
|---|---|---|---|
| Film | Thickness (Å) | 450° C. (%) | 500° C. (%) |
| Aluminum oxide | 100 | 95 | 96 |
| N-doped silicon | 250 | 90 | 82 |
| carbide | | | |

These experiments show that diffusion barrier layers can be very effective in reducing diffusion of labile species from a first layer into a second layer. As described above in relation to FIGS. 1A-1C and 2A-2C, particularly FIGS. 1C and 2C, reducing diffusion of the labile species in one direction (e.g., from an underlayer downwards into underlying layers such as the diffusion barrier layer, hardmask layer, etc.) results in relatively greater diffusion in the opposite direction (e.g., from the underlayer upwards into an overlying layer such as a radiation-sensitive imaging layer). This opposite/upwards diffusion results in desirable chemical changes, for example within the radiation-sensitive imaging layer, as described in relation to FIGS. 3A and 3B. As such, the inclusion of a diffusion barrier layer between an underlayer and a hardmask, as shown in FIG. 2A, can be used to maximize diffusion of the labile species into the radiation-sensitive imaging layer, thereby maximizing the desirable chemical changes that occur within the radiation-sensitive imaging layer as a result of this diffusion.

### Definitions

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. Such an aliphatic can be unsubstituted or substituted with one or more groups, such as groups described herein for an alkyl group.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15)N-protected amino; (16) nitro (e.g., —NO₂); (17) oxo (e.g., ═O); (18) —CO₂R^{A} where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “amino” is meant —NR^{N1}R^{N2}, where each of R^{N1} and R^{N2} is, independently, H, optionally substituted alkyl, or optionally substituted aryl, or R^{N1} and RN², taken together with the nitrogen atom to which each are attached, form a heterocyclyl group, as defined herein.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. Such an aromatic can be unsubstituted or substituted with one or more groups, such as groups described herein for an alkyl or aryl group. Yet other substitution groups can include aliphatic, haloaliphatic, halo, nitrate, cyano, sulfonate, sulfonyl, or others.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl. In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “carbide” is meant a compound including at least one carbon atom and at least one other element.

By “carbonyl” is meant a —C(O)— group, which can also be represented as >C═O, or a —CO group.

By “carboxyl” is meant a —CO₂H group.

By “carboxyaldehyde” is meant a —C(O)H group.

By “cyano” is meant a —CN group.

By “cycloalkenyl” is meant a monovalent unsaturated non-aromatic or aromatic cyclic hydrocarbon group of from three to eight carbons, unless otherwise specified, having one or more double bonds. The cycloalkenyl group can also be substituted or unsubstituted. For example, the cycloalkenyl group can be substituted with one or more groups including those described herein for alkyl.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “diffusion barrier layer” is meant a layer of material positioned between an underlayer and a hardmask layer, where the material of the diffusion barrier layer reduces diffusion of a labile species from the underlayer into the hardmask layer.

By “dose” is meant the amount of radiation provided to a semiconductor substrate to induce chemical changes in a radiation-sensitive layer during a photolithography operation.

By “ester” as used herein is meant —OC(O)A¹ or —C(O)OA¹, where A¹ can be an alkyl, alkenyl, alkynyl, aryl, heteroaryl, cycloalkyl, cycloalkenyl, heterocycloalkyl, or heterocycloalkenyl group, as described herein.

By “halo” is meant F, Cl, Br, or I.

By “haloalkyl” is meant an alkyl group, as defined herein, substituted with one or more halo.

By “hardmask” is meant a material that acts as a mask during an etching operation, and which is not a soft mask material such as conventional soft organic polymer resists.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. The heterocyclyl group can be substituted or unsubstituted. For example, the heterocyclyl group can be substituted with one or more substitution groups, as described herein for alkyl.

By “heterocyclyloxy” is meant a heterocyclyl group, as defined herein, attached to the parent molecular group through an oxygen atom.

By “heterocyclyloyl” is meant a heterocyclyl group, as defined herein, attached to the parent molecular group through a carbonyl group.

By “hydrocarbyl” is meant a univalent group formed by removing a hydrogen atom from a hydrocarbon. Non-limiting unsubstituted hydrocarbyl groups include alkyl, alkenyl, alkynyl, and aryl, as defined herein, in which these groups include only carbon and hydrogen atoms. The hydrocarbyl group can be substituted or unsubstituted. For example, the hydrocarbyl group can be substituted with one or more substitution groups, as described herein for alkyl. In other embodiments, any alkyl or aryl group herein can be replaced with a hydrocarbyl group, as defined herein. As used herein, “hydrocarbyl-terminated” is used interchangeably with hydrocarbon-terminated, and refers to compounds having a formula that is (CₓH_{y})-terminated.

By “homogeneous” is meant uniform. A layer that is homogeneous is uniform in composition. A homogeneous layer may be a single material, or it may be a uniform mixture of two or more materials. A homogeneous layer does not have a composition gradient, nor does it have a non-uniform combination of two or more materials.

By “hydroxyl” is meant —OH.

By “labile species” is meant a species that is likely to move within a first material (e.g., the material where the labile species originates) or from a first material to a second material (e.g., from the material where the labile species originates to a neighboring material).

By “metaloxy polymer” is meant a polymer that includes both metal atoms and oxygen atoms. The metal atoms may or may not be directly bonded to the oxygen atoms.

By “negative photoresist” is meant a photoresist in which the portion of the photoresist that is exposed to light becomes insoluble to the photoresist developer or is otherwise selectively retained after exposure to radiation.

By “nitride” is meant a compound including at least one nitrogen atom and at least one other element.

By “nitro” is meant an —NO₂ group.

By “non-homogeneous” is meant not uniform. A non-homogeneous layer has a non-uniformity with respect to at least one property. A non-homogeneous layer may include a non-uniform mixture of two or more materials. A non-homogeneous layer may also include a gradient with respect to one or more properties.

By “oxide” is meant a compound including at least one oxygen atom and at least one other element.

By “oxo” is meant an ═O group.

By “oxy” is meant —O—.

By “oxycarbide” is meant a compound including at least one oxygen atom and at least one carbon atom.

By “oxynitride” is meant a compound including at least one oxygen atom and at least one nitrogen atom.

By “patterning structure” is meant a partially fabricated semiconductor device intended for use in photolithography.

By “photocrosslinking” is meant a material that crosslinks when exposed to radiation.

By “photodecomposable” is meant a material that generates hydrophilic products under radiation.

By “photopolymeric” is meant a material that initiates polymerization upon exposure to radiation. Such materials typically generate free radicals upon exposure to radiation.

By “positive photoresist” is meant a photoresist in which the portion of the photoresist that is exposed to radiation becomes soluble to the photoresist developer or is otherwise selectively removed after exposure to radiation.

By “radiation-sensitive imaging layer” is meant a layer of material that is susceptible to change upon exposure to radiation, such as during a photolithography operation.

By “radiolysable ligands” is meant an ion or molecule that binds to a central atom to form a complex, which is capable of being severed from the central atom through application of radiation. As used herein, the terms radiolysable and radiation-cleavable are used interchangeably.

By “sulfonyl” is meant —S(O)₂A¹, where A¹ can be hydrogen, an alkyl, halogenated alkyl, alkenyl, alkynyl, aryl, heteroaryl, cycloalkyl, cycloalkenyl, heterocycloalkyl, or heterocycloalkenyl group, as described herein.

By “thio” is meant an —S— group.

By “thiol” is meant an —SH group.

By “underlayer” is meant a layer positioned between a radiation-sensitive imaging layer and a hardmask layer, and which includes a labile species as described herein.

As used herein, the term “about” means+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A patterning structure comprising:
a substrate comprising a partially fabricated semiconductor device film stack;
a radiation-sensitive imaging layer disposed over the substrate;
an underlayer positioned below the radiation-sensitive imaging layer, the underlayer comprising a labile species;
a hardmask layer positioned below the underlayer; and
a diffusion barrier layer positioned between the underlayer and the hardmask layer, the diffusion barrier layer comprising a diffusion barrier material that reduces diffusion of the labile species from the underlayer into the hardmask layer.

2. The patterning structure of claim 1, wherein the diffusion barrier material comprises a material selected from the group consisting of an oxide material, a nitride material, a carbide material, silicon, a silicide material, a sulfide material, a metal-containing material, or a combination thereof.

3. The patterning structure of claim 2, wherein the diffusion barrier material comprises the oxide material, and wherein the oxide material is a material selected from the group consisting of a metal oxide, a silicon oxide, a metal oxynitride, a silicon oxynitride, a metal oxycarbide, a silicon oxycarbide, or a combination thereof, and optionally wherein the diffusion barrier material comprises a metal selected from the group consisting of aluminum, titanium, molybdenum, tungsten, tin, or a combination thereof.

4. The patterning structure of claim 2, wherein the diffusion barrier material comprises the nitride material, and wherein the nitride material is a material selected from the group consisting of a metal nitride, a silicon nitride, a metal oxynitride, a silicon oxynitride, or a combination thereof, and optionally wherein the diffusion barrier material comprises a metal selected from the group consisting of aluminum, titanium, molybdenum, tungsten, tin, or a combination thereof.

5. The patterning structure of claim 2, wherein the diffusion barrier material comprises the carbide material, and wherein the carbide material is a material selected from the group consisting of a metal carbide, a silicon carbide, a metal oxycarbide, a silicon oxycarbide, or a combination thereof, and optionally wherein the diffusion barrier material comprises a metal selected from the group consisting of aluminum, titanium, molybdenum, tungsten, tin, or a combination thereof.

6. The patterning structure of claim 5, wherein the diffusion barrier material comprises the silicon carbide, and wherein the silicon carbide is doped with at least one of nitrogen and oxygen.

7. The patterning structure of claim 1, wherein the labile species is hydrogen.

8. The patterning structure of claim 1, wherein the radiation-sensitive imaging layer comprises a photoresist material, optionally wherein the photoresist material is a metal-containing photoresist material, and optionally wherein the photoresist material is a metal-organic-containing photoresist material.

9. The patterning structure of claim 1, wherein the underlayer comprises hydrogen-containing carbon layer comprising at least one dopant, wherein the at least one dopant is a dopant selected from the group consisting of oxygen, silicon, nitrogen, tungsten, boron, iodine, chlorine, or a combination thereof, and wherein the diffusion barrier layer is deposited using a dry vapor-based deposition technique or using a wet liquid-based deposition technique.

10. The patterning structure of claim 1, wherein the diffusion barrier layer reduces diffusion of the labile species from the underlayer into the hardmask layer by at least about 60%, or by at least about 90%.

11. A method of making a patterning structure, the method comprising:
providing a substrate having a hardmask layer thereon;
depositing a diffusion barrier layer over the hardmask layer, the diffusion barrier layer comprising a diffusion barrier material;
depositing an underlayer over the diffusion barrier layer, the underlayer comprising a labile species; and
depositing a radiation-sensitive imaging layer over the underlayer,
wherein the diffusion barrier layer reduces diffusion of the labile species from the underlayer into the hardmask layer.

12. The method of claim 11, wherein the diffusion barrier material comprises a material selected from the group consisting of an oxide material, a nitride material, a carbide material, silicon, a silicide material, a sulfide material, a metal-containing material, or a combination thereof.

13. The method of claim 12, wherein the diffusion barrier material comprises the oxide material, and wherein the oxide material is a material selected from the group consisting of a metal oxide, a silicon oxide, a metal oxynitride, a silicon oxynitride, a metal oxycarbide, a silicon oxycarbide, or a combination thereof, and optionally wherein the diffusion barrier material comprises a metal selected from the group consisting of aluminum, titanium, molybdenum, tungsten, tin, or a combination thereof.

14. The method of claim 12, wherein the diffusion barrier material comprises the nitride material, and wherein the nitride material is a material selected from the group consisting of a metal nitride, a silicon nitride, a metal oxynitride, a silicon oxynitride, or a combination thereof, and optionally wherein the diffusion barrier material comprises a metal selected from the group consisting of aluminum, titanium, molybdenum, tungsten, tin, or a combination thereof.

15. The method of claim 12, wherein the diffusion barrier material comprises the carbide material, and wherein the carbide material is a material selected from the group consisting of a metal carbide, a silicon carbide, a metal oxycarbide, a silicon oxycarbide, or a combination thereof, and optionally wherein the diffusion barrier material comprises a metal selected from the group consisting of aluminum, titanium, molybdenum, tungsten, tin, or a combination thereof.

16. The method of claim 15, wherein the diffusion barrier material comprises the silicon carbide, and wherein the silicon carbide is doped with at least one of nitrogen and oxygen.

17. The method of claim 11, wherein the labile species is hydrogen.

18. The method of claim 11, wherein the radiation-sensitive imaging layer comprises a photoresist material, optionally wherein the photoresist material is a metal-containing photoresist material, and optionally wherein the photoresist material is a metal-organic-containing photoresist material.

19. The method of claim 11, wherein the underlayer comprises hydrogen-containing carbon layer comprising at least one dopant, wherein the at least one dopant is a dopant selected from the group consisting of oxygen, silicon, nitrogen, tungsten, boron, iodine, chlorine, or a combination thereof, and wherein the diffusion barrier layer is deposited using a dry vapor-based deposition technique or using a wet liquid-based deposition technique.

20. The method of claim 11, wherein the diffusion barrier layer reduces diffusion of the labile species from the underlayer into the hardmask layer by at least about 60%, or by at least about 90%.
